(19) United States
(12) Patent Application Publication
(10) Pub. No.: US 2024/0103588 A1
(43) Pub. Date: Mar. 28, 2024

(54) Camera Module for a Portable Electronic Device

(71) Applicant: Apple Inc., Cupertino, CA (US)

(72) Inventors: Noah D Bedard, Los Gatos, CA (US); Matthew T Craven, Plains, PA (US); Brad G Boozer, Campbell, CA (US)

(73) Assignee: Apple Inc., Cupertino, CA (US)

(21) Appl. No.: 18/470,352

(22) Filed: Sep. 19, 2023

Related U.S. Application Data
(60) Provisional application No. 63/376,982, filed on Sep. 23, 2022.

(51) Int. Cl. G06F 1/16; H04N 23/51; H04N 23/57

(52) U.S. Cl. CPC G06F 1/1686; G06F 1/1626; H04N 23/51; H04N 23/57

(57) ABSTRACT

A portable electronic device is provided. The portable electronic device includes a camera module having an optical axis. The portable electronic device also includes a display panel. The portable electronic device further includes a display printed circuit board (PCB) including a cutout centered around the optical axis. In addition, the portable electronic device includes a mounting bracket fixedly coupling the camera module to the display PCB. The portable electronic device includes a housing configured to retain the camera module, the display panel, the display PCB, and the mounting bracket therein. In some aspects, the mounting bracket may be fixedly attached to an interior surface within the portable electronic device and configured to maintain a position of the camera module.

This application claims benefit of priority to U.S. Provisional Application Ser. No. 63/376,982, entitled “Camera Module for a Portable Electronic Device,” filed Sep. 23, 2022, and which is hereby incorporated herein by reference in its entirety.

### BACKGROUND

### Technical Field

This disclosure relates generally to camera module for a portable electronic device, and particularly, mounting a camera module in a portable electronic device.

### Description of the Related Art

The advent of small, mobile multipurpose devices such as smartphones, smart watches, and tablet or pad devices has resulted in a need for high-resolution, small form factor cameras for integration in the devices. Some cameras may incorporate optical image stabilization (OIS) mechanisms that may sense and react to external excitation/disturbance by adjusting location of the optical lens on the X and/or Y axis in an attempt to compensate for unwanted motion of the lens. Furthermore, some cameras may incorporate an autofocus (AF) mechanism whereby the object focal distance can be adjusted to focus an object plane in front of the camera at an image plane to be captured by the image sensor. In some such AF mechanisms, the optical lens is moved as a single rigid body along the optical axis of the camera to refocus the camera. Many devices, due to the small size, may contain many tightly integrated components. Some cameras may be strategically mounted to these devices to accommodate the tight tolerances created by the many tightly integrated components.

### BRIEF DESCRIPTION OF THE DRAWINGS

FIG. 1 illustrates an example electronic device having a transparent cover covering a display screen, in accordance with some embodiments.

FIG. 2 illustrates an overhead view of at least some components for front-crystal integration of a camera module into an electronic device, in accordance with some embodiments.

FIG. 3 illustrates a cross-sectional view of at least some components for front-crystal integration of a camera module into an electronic device across an A-A plane, in accordance with some embodiments.

FIG. 4 illustrates an underneath view of at least some components for front-crystal integration of a camera module into an electronic device across the A-A plane, in accordance with some embodiments.

FIG. 5 illustrates an exploded view of at least some of the components for front-crystal integration of a camera module into an electronic device in accordance with some embodiments.

FIG. 6 illustrates an overhead view of at least some components for housing-side integration of a camera module into an electronic device, in accordance with some embodiments.

FIG. 7 illustrates a cross-sectional view of at least some components for housing-side integration of a camera module into an electronic device across an B-B plane, in accordance with some embodiments.

FIG. 8 illustrates an underneath view of at least some components for housing-side integration of a camera module into an electronic device across the B-B plane, in accordance with some embodiments.

FIG. 9 illustrates an exploded view of at least some of the components for housing-side integration of a camera module into an electronic device, in accordance with some embodiments.

FIG. 10 illustrates a cross-sectional overhead view of a configuration of an electronic device, in accordance with some embodiments.

FIG. 11 illustrates a cross-sectional overhead view of an electronic device, in accordance with some embodiments.

FIG. 12 illustrates a cross-sectional overhead view of an electronic device, in accordance with some embodiments.

FIG. 13 illustrates a cross-sectional overhead view of an electronic device, in accordance with some embodiments.

FIG. 14 illustrates a cross-sectional overhead view of a configuration of an electronic device, in accordance with some embodiments.

FIG. 15 illustrates a cross-sectional overhead view of an electronic device, in accordance with some embodiments.

FIG. 16 illustrates a cross-sectional overhead view of an electronic device, in accordance with some embodiments.

FIG. 17 illustrates a cross-sectional view of a configuration of an electronic device, in accordance with some embodiments.

FIG. 18 illustrates a cross-sectional view of an electronic device, in accordance with some embodiments.

FIG. 19 illustrates a cross-sectional view of an electronic device, in accordance with some embodiments.

FIG. 20 illustrates a cross-sectional view of a camera display package, in accordance with some embodiments.

FIG. 21 illustrates a cross-sectional view of a camera display package, in accordance with some embodiments.

FIG. 22 illustrates a cross-sectional view of a camera display package, in accordance with some embodiments.

FIG. 23 illustrates a schematic representation of an example device that may include a camera, in accordance with some embodiments.

FIG. 24 illustrates a schematic block diagram of an example computing device, referred to as computer system, that may include or host embodiments of a camera, in accordance with some embodiments.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

“Comprising.” This term is open-ended. As used in the appended claims, this term does not foreclose additional structure or steps. Consider a claim that recites: “An apparatus comprising one or more processor units . . . .” Such a claim does not foreclose the apparatus from including additional components (e.g., a network interface unit, graphics circuitry, etc.).

“Configured To.” Various units, circuits, or other components may be described or claimed as “configured to” perform a task or tasks. In such contexts, “configured to” is used to connote structure by indicating that the units/circuits/components include structure (e.g., circuitry) that performs those task or tasks during operation. As such, the unit/circuit/component can be said to be configured to perform the task even when the specified unit/circuit/component is not currently operational (e.g., is not on). The units/circuits/components used with the “configured to” language include hardware—for example, circuits, memory storing program instructions executable to implement the operation, etc. Reciting that a unit/circuit/component is “configured to” perform one or more tasks is expressly intended not to invoke 35 U.S.C. § 112, sixth paragraph, for that unit/circuit/component. Additionally, “configured to” can include generic structure (e.g., generic circuitry) that is manipulated by software and/or firmware (e.g., an FPGA or a general-purpose processor executing software) to operate in manner that is capable of performing the task(s) at issue. “Configure to” may also include adapting a manufacturing process (e.g., a semiconductor fabrication facility) to fabricate devices (e.g., integrated circuits) that are adapted to implement or perform one or more tasks.

“First,” “Second,” etc. As used herein, these terms are used as labels for nouns that they precede, and do not imply any type of ordering (e.g., spatial, temporal, logical, etc.). For example, a buffer circuit may be described herein as performing write operations for “first” and “second” values. The terms “first” and “second” do not necessarily imply that the first value must be written before the second value.

“Based On.” As used herein, this term is used to describe one or more factors that affect a determination. This term does not foreclose additional factors that may affect a determination. That is, a determination may be solely based on those factors or based, at least in part, on those factors. Consider the phrase “determine A based on B.” While in this case, B is a factor that affects the determination of A, such a phrase does not foreclose the determination of A from also being based on C. In other instances, A may be determined based solely on B.

It will also be understood that, although the terms first, second, etc. may be used herein to describe various elements, these elements should not be limited by these terms. These terms are only used to distinguish one element from another. For example, a first contact could be termed a second contact, and, similarly, a second contact could be termed a first contact, without departing from the intended scope. The first contact and the second contact are both contacts, but they are not the same contact.

The terminology used in the description herein is for the purpose of describing particular embodiments only and is not intended to be limiting. As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context.

### DETAILED DESCRIPTION

Various embodiments described herein relate to integrating a camera module into an electronic device, for example, behind a display panel and/or a display PCB. For example, a camera module may be integrated into an electronic device using a front-crystal (FC) integration. For example, a camera module may be assembled into the FC or the display so that the camera module resides on the display. As another example, a camera module may be integrated into an electronic device using a housing-side integration. For example, a camera module may be fixedly attached to the housing of the electronic device and compressed against an alert bracket via a bracket so that the camera module resides at a fixed position within the electronic device. In some aspects, a camera module may be placed within a corner of the electronic device. The display in front of the camera module may optionally maintain emissive pixelation such that the camera module is hidden behind the display panel. In some aspects, the display region above the camera module may include removed pixelation such as a hole or notch in the display panel. In at least these configurations, the camera module may be positioned along a center axis of the electronic device for symmetrical aesthetics.

In some aspects, an electronic device may include a camera module positioned behind an emissive display hiding the camera module to attain improved aesthetics and for better fit and configurations. Some display panels may be very opaque allowing little light to pass therethrough to the camera module. A display panel may include a high light transmission region (e.g., an enhanced light transmission region) for increasing light transmission to the camera module without compromising the entire display panel. The high light transmission region may include a hole punch through the display panel (e.g., a pin-hole sized hole punch), a notch, or a region with low pixel count or routing density. The size of the high light transmission region may depend on several camera module parameters including field-of-view, entrance pupil size and position, lens barrel dimensions, F number, and the like. The high light transmission region may be co-designed with the camera module parameters to enable a smaller high light transmission region and better camera module performance.

Reference will now be made in detail to embodiments, examples of which are illustrated in the accompanying drawings. In the following detailed description, numerous specific details are set forth in order to provide a thorough understanding of the present disclosure. However, it will be apparent to one of ordinary skill in the art that some embodiments may be practiced without these specific details. In other instances, well-known methods, procedures, components, circuits, and networks have not been described in detail so as not to unnecessarily obscure aspects of the embodiments.

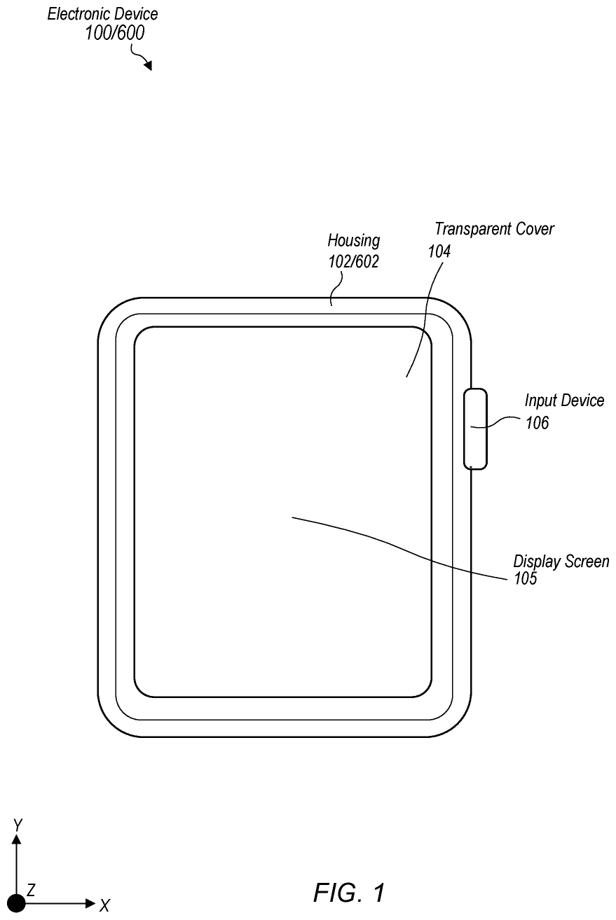

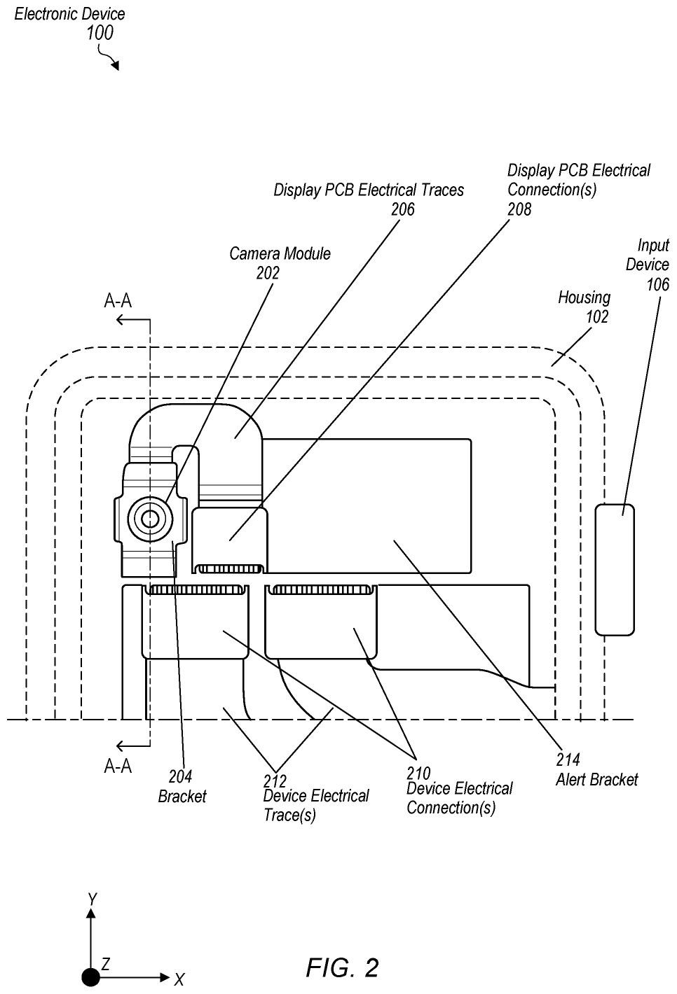

FIG. 1 illustrates an example electronic device 100/600 having a transparent cover covering a display screen, according to at least some embodiments. FIG. 1 shows an overhead view of the exterior of the electronic device 100/600. The electronic device 100/600 may include one or more same or similar features as the features described with respect to or illustrated in FIGS. 2, 3, 4, 5, 6, 7, 8, 9, 10, 11, 12, 13, 14, 15, 16, 17, 18, 19, 20, 21, 22, 23, and 24. The example X-Y-Z coordinate system shown in FIG. 1 is used to discuss aspects of components and/or systems, and may apply to embodiments described throughout this disclosure. FIG. 1, as with the other included figures, is shown for illustrative purposes and does not limit either the possible embodiments of the present invention or the claims.

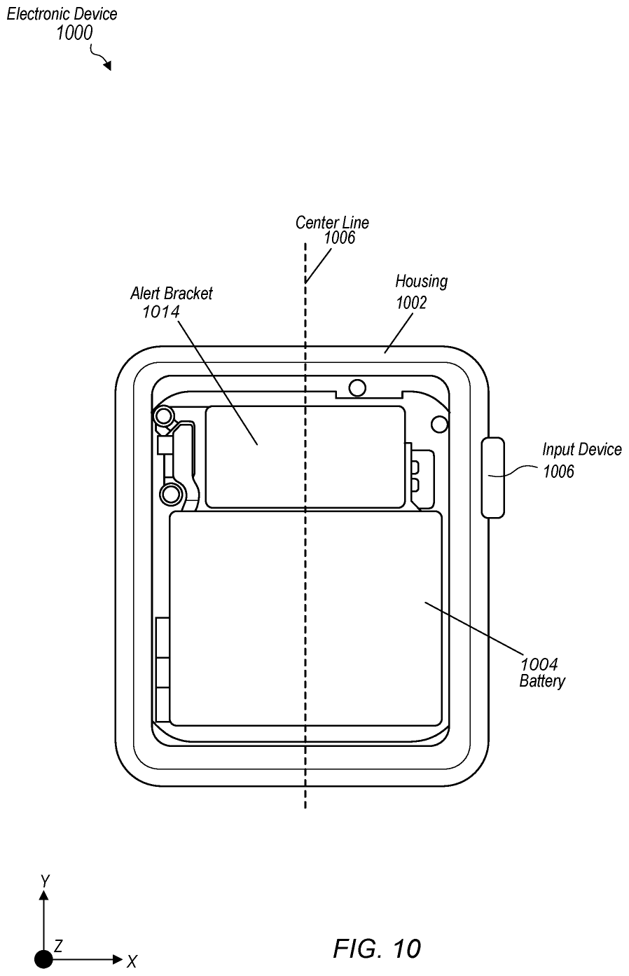

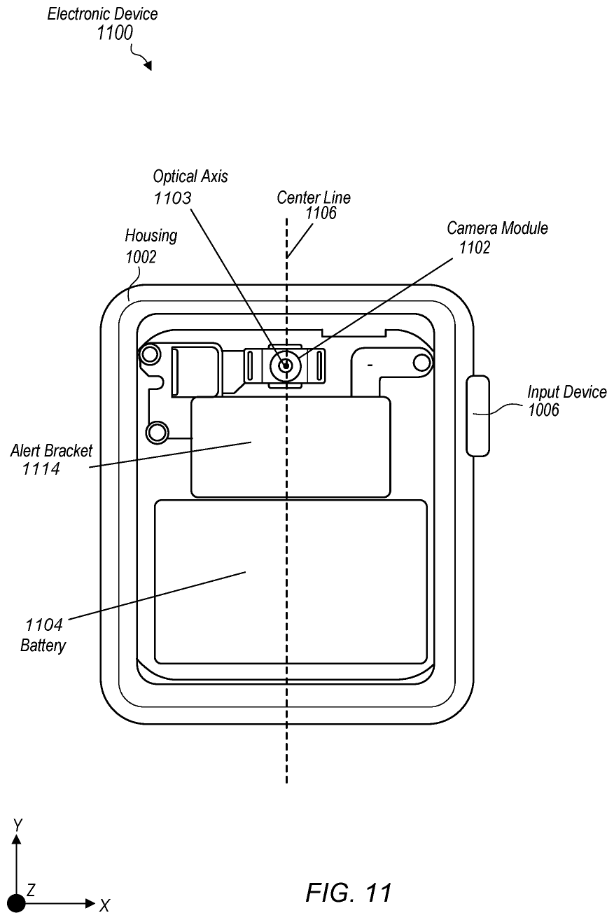

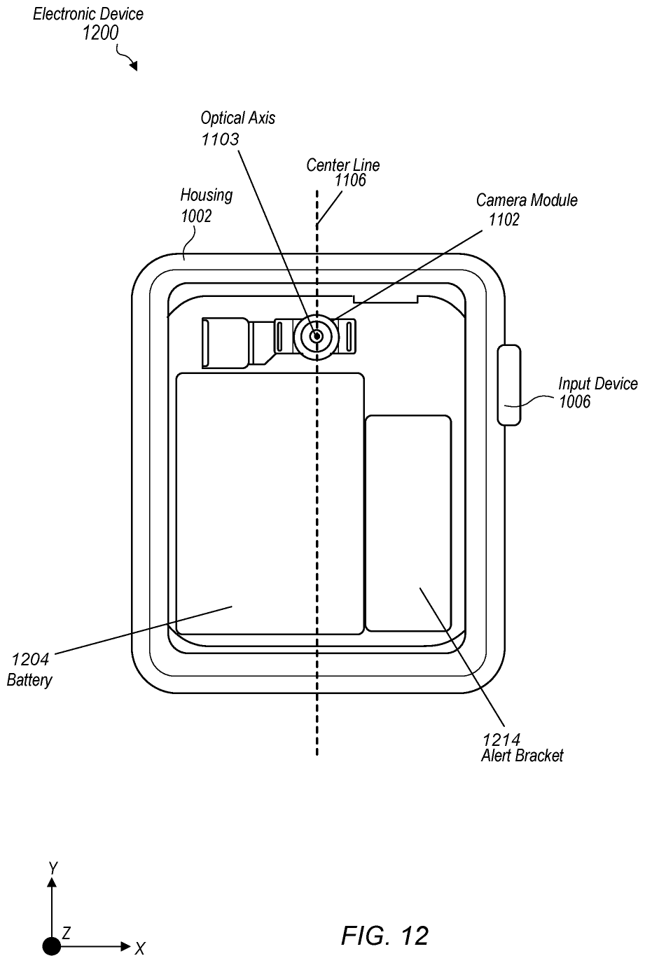

As shown in FIG. 1, the electronic device 100/600 may include a housing 102/602 supporting a transparent cover 104 covering a display screen 105, and one or more control buttons 106. In this example, electronic device 100/600 may be a wearable computing device (e.g., a smart watch), though other embodiments may be incorporated in other electronic devices such as portable computing devices, tablet computers, desktop computers, laptops, all-in-one computers, smart phones, storage devices, portable media players, navigation systems, monitors, power supplies, video delivery systems, adapters, remote control devices, chargers, and other devices. In some aspects, the display screen 105 may be a touch screen. The electronic device 100/600 may further include an internal battery (e.g., a battery 1004 illustrated in FIGS. 10 and 11, a battery 1204 illustrated in FIG. 12). This internal battery may be charged inductively or through a connector. The battery may provide power for components of the electronic device 100/600, such as the display screen 105. The display screen 105 may be used by applications running on electronic device 100/600 to provide information to a user. The display screen 105 may also be used to provide other information, such as information regarding a state of charge of the battery. For example, a graphic indicator showing a percentage of remaining battery capacitor may be provided to a user on the display screen 105.

In some aspects, the electronic device 100/600 may contain tightly integrated components increasing the challenge to include additional modules into the system of the electronic device 100/600. For example, integrating a camera module into the electronic device 100/600 may be difficult due to the tightly integrated components of the system, the manufacturing processes used to assembly the electronic device 100/600, and/or the placement of the lens of the camera module relative to the display screen 105. As described herein, a plurality of embodiments may be used to integrate a camera module into the electronic device 100/600. For example, a camera module may be integrated into the electronic device 100/600 using front-crystal integration and/or housing-side integration. Also, as described further herein, system layout for camera placement at a variety of locations with the electronic device 100/600 may be provided.

As described herein, a camera module may be integrated into an electronic device using a front-crystal (FC) integration. For example, a camera module may be assembled into the FC or the display so that the camera module resides on the display. FC integration of the camera module may provide easier camera module calibration and functional checks without having fully assembly the electronic device. With FC integration, positional tolerances of the camera module with respect to the display may be tight because the camera module may have to look through traces and light emitting diodes (LEDs) on the display. In some aspects, a curvature on the display may affect the camera module enhancing the need for tight positional tolerances of the camera module with respect to the display.

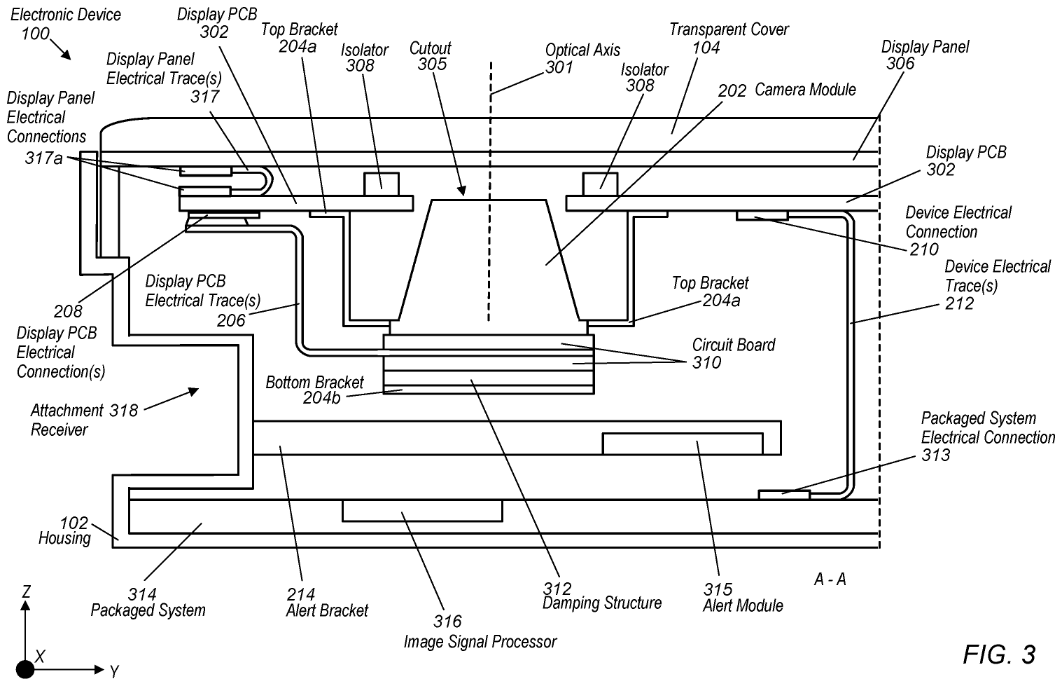

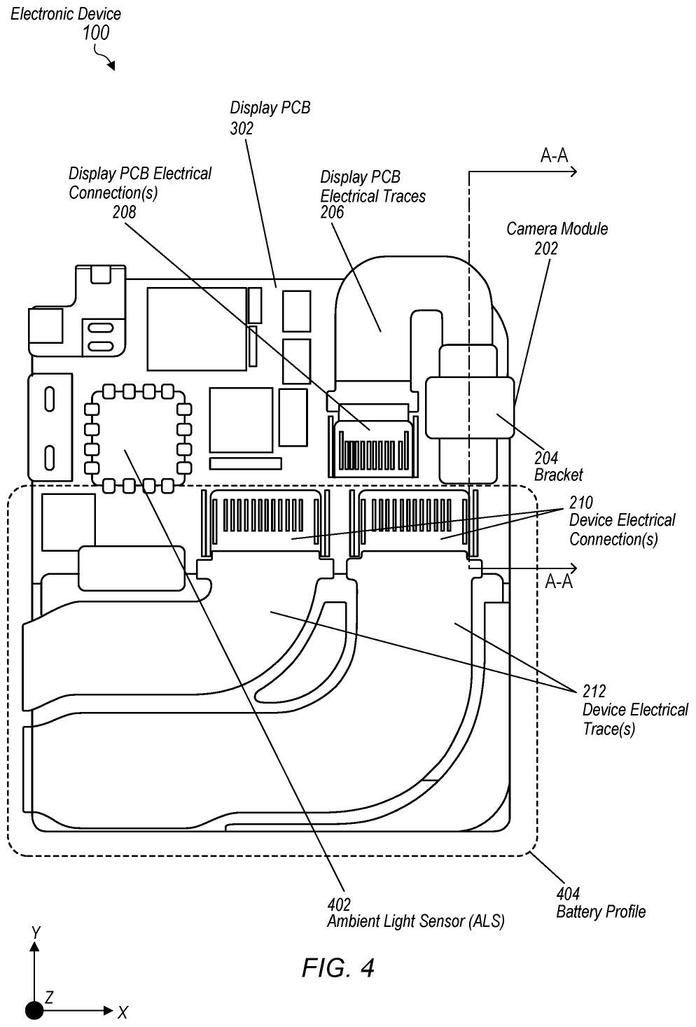

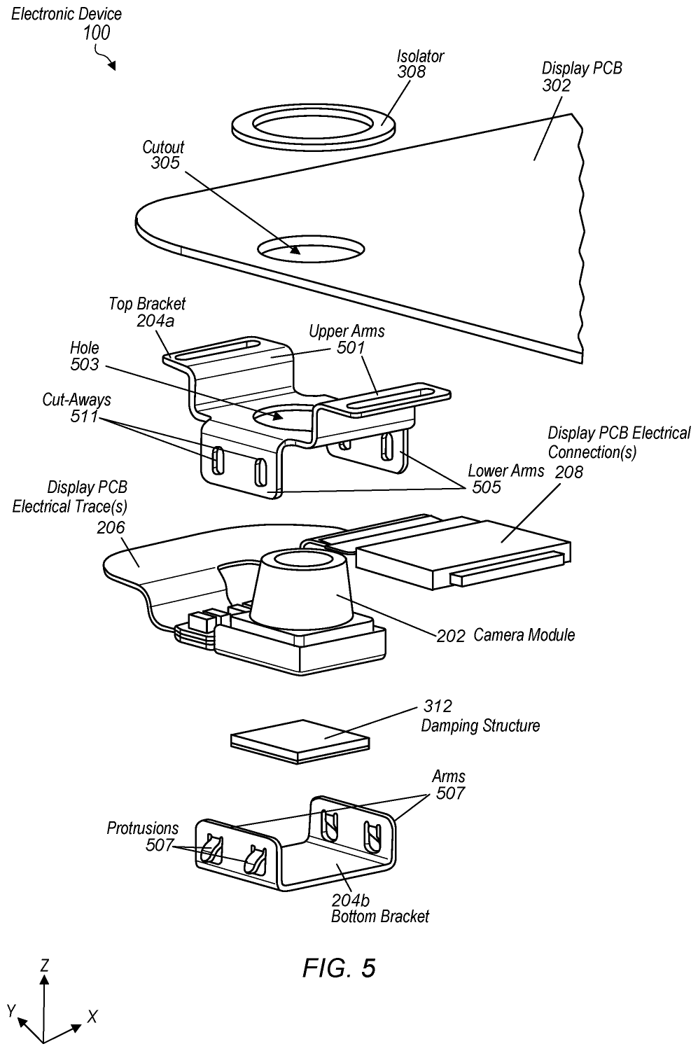

FIGS. 2, 3, 4, and 5 illustrate components to be used with a camera module 202 for FC integration of a camera module 202 into the electronic device 100, according to some embodiments. FIG. 2 shows an overhead view of at least some components of the electronic device 100. FIG. 3 shows a cross-sectional view of the electronic device 100 across the A-A plane. FIG. 4 shows an underneath view of at least some components of the electronic device 100 across the A-A plane. FIG. 5 shows an exploded view of at least some of the components of the electronic device 100. The electronic device 100 may include one or more same or similar features as the features described with respect to or illustrated in FIGS. 1, 6, 7, 8, 9, 10, 11, 12, 13, 14, 15, 16, 17, 18, 19, 20, 21, 22, 23, and 24. The example X-Y-Z coordinate system shown in FIGS. 2, 3, 4, and 5 may be used to discuss aspects of components and/or systems, and may apply to embodiments described throughout this disclosure. FIGS. 2, 3, 4, and 5, as with the other included figures, is shown for illustrative purposes and does not limit either the possible embodiments of the present invention or the claims.

As shown in FIG. 2, the electronic device 100 may include a camera module 202, a bracket 204, one or more camera electrical traces 206 attached to one or more camera electrical connections 208, one or more device electrical traces 212 attached to one or more device electrical connections 210, and an alert bracket 214. The camera module 202 may be used for photography to capture images for viewing by a person. In some aspects, the camera module 202 may be a machine vision camera module (e.g., in addition to a photography camera module, as an alternative to a photography camera module). A machine vision camera module may be smaller than a photography camera module and may captures images that are not meant to be seen by a human and instead are processed by one or more machine learning algorithms. For example, a machine vision camera module may capture monochromic images and/or infrared images for processing face identification, authentication, and/or object/face tracking.

The housing 102 may contain or house the camera module 202, the bracket 204, the one or more camera electrical traces 206 attached to the one or more camera electrical connections 208, the one or more device electrical traces 212 attached to one or more device electrical connections 210, and the alert bracket 214. In some aspects, the housing 202 may include an attachment receiver 318. The attachment receiver 318 may be configured to receive an attachment device for attaching the electronic device 100 to another object (e.g., an object external to or separate from the electronic device 100). For example, the attachment receiver 318 may be configured to receive a strap, a band, or a clamp for attaching the electronic device 100 to a body (e.g., a human body, an animal body), a stand, a hook, or a pole. As described further herein, the bracket 204 may fixedly attach the camera module 202 to a display PCB (e.g., a display PCB 302 illustrated in FIG. 3). The alert bracket 214 may include an alert module (e.g., an alert module 315 illustrated in FIG. 3) configured to provide a physical indication through the electronic device 100 that an event has occurred. For example, in response to determining that a battery of the electronic device 100 is below a threshold, an alert module residing in/on the alert bracket 214 may vibrate causing vibration of the entire electronic device 100. As another example, in response to determining that a battery of the electronic device 100 is fully charged, an alert module residing in/on the alert bracket 214 may emit a sound indicating that the electronic device 100 is fully charged. The alert bracket 214 may include one or more alert modules such as a vibration alert module, a speaker alert module, or the like.

The one or more camera electrical traces 206 may be used to communicate image data from an image sensor of the camera module 202 to a packaged system (e.g., a system on a chip (SOC)) (e.g., a packaged system 314 illustrated in FIG. 3), for example, an image signal processor (ISP) (e.g., an ISP 316 illustrated in FIG. 3) residing in/on or included within the packaged system. As described further herein, the one or more camera electrical connections 208 (e.g., zero insertion force (ZIF) connection(s)) may electronically connect the camera module 202 (e.g., an image sensor of the camera module 202), via the one or more camera electrical traces 206 to the display PCB (e.g., the display PCB 302 illustrated in FIG. 3). The one or more device electrical traces 212 may be in electrical communication with the packaged system (e.g., an ISP residing in the packaged system) via a packaged system electrical connection (e.g., a packaged system electrical connection 313 illustrated in FIG. 3) and the display PCB via the one or more device electrical connections 210 (e.g., a ZIF connection). Thus, the camera module 202 (e.g., an image sensor of the camera module 202) may be in electronic communication with and communicate image data to the ISP (residing in the packaged system) via the one or more camera electrical connections 208, the one or more camera electrical traces 206, the display PCB, the one or more device electrical connections 210, the one or more device electrical traces 212, and the one or more package system electrical connections.

As shown in FIG. 3, and as described herein, the electronic device 100 may include the camera module 202, the bracket 204, the one or more camera electrical traces 206 attached to the one or more camera electrical connections 208, the one or more device electrical traces 212 attached to the one or more device electrical connections 210, and the alert bracket 214 including the alert module 315. The electronic device 100 may also include a display PCB 302, a display panel 306, and the transparent cover 104 residing over the display PCB 304 and the display panel 306. The display PCB 302 may be electrically connected to the display panel 306, via the display panel electrical trace(s) 317 and the display panel electrical connections 317a, and may be configured to command pixels on the display panel 306 to individually luminate a particular color and a particular brightness for image display. In some aspects, the display panel 306 may be an organic light emitting diode (OLED) display, a micro LED display, an liquid crystal display (LCD), or the like.

In some aspects, the bracket 204 may fixedly attach the camera module 202 to the display PCB 302. As shown in FIG. 3, the bracket 204 may include a top bracket 204a and a bottom bracket 204b. The top bracket 204a may fastened (e.g., welded, laser welded) to a bottom surface of the display PCB 302 and retain the camera module 202 in a fixed position in the x-direction and the y-direction (e.g., fixed in one or more directions orthogonal to the optical axis 301). The top bracket 204 may couple to the bottom bracket 204b so that the bottom bracket 204b retains the camera module 202 at a fixed position in the z-direction (e.g., fixed or retain in one or more directions parallel to the optical axis 301). As shown in FIG. 5, the top bracket 204a surrounds the camera module 202 for retaining the camera module 202 in a fixed position in the x-direction and the y-direction. Also, as shown in FIG. 5, the bottom bracket 204 has a “U-shape” for retaining the camera module 202 at a fixed position in the z-direction. In addition, due the “U-shape” of the bottom bracket 204, the circuit board 310 may also be retained at a fixed position in the z-direction while allowing the camera electrical trace(s) 206 to extend from the circuit board 310 (e.g., through an open end of the “U-shape”) and connect (e.g., physically connect, electrically connect) to the display PCB 302. In some aspects, a damping structure 312 positioned between the camera module 202 and the bottom bracket 204b (e.g., between the circuit board 310 and the bottom bracket 204b) may dampen movement of the camera module 202 in the z-direction, for example, in response to a drop event. In some aspects, the damping structure 312 may include a foam pad, one or more springs, or a cushion.

As described herein, the bracket 204 retains the camera module 202 in a fixed position within the electronic device 100. The bracket 204 also aligns the camera module 202 with a cutout 305 extending through the display PCB 302 so that the cutout 305 is centered around the optical axis 301 of the camera module 202. With the cutout 305 aligned with the optical axis 301 of the camera module 202, the camera module 202 may be able to receive light through the display panel 306 to capture an image. In some aspects, an isolator 308 (e.g., ring) positioned on the display PCB 302 and surrounding the cutout 305 may be configured to isolate light from a volume between the display panel 306 and the camera module 202. In some aspects, the isolator 308 may also be configured to keep dust and particles away from the lens of the camera module 202. In some aspects, the camera module 202 may receive light through cutout 305 and the display panel 306 for image capture. In some aspects, the display PCB 302 may command an area of the display panel 306 over the camera module 202 to allow more light to pass through the display panel 306 so that the camera module 202 may capture an image. In some aspects, the display panel 306 may include a hole to allow light to pass through so that the camera module 202 may capture an image. In some aspects, the display panel 306 may include a small region aligned with the optical axis 301 and having a high transparency (e.g., relative to a remaining portion of the display panel 306 so that the camera module receives light for image capture.

The one or more camera electrical traces 206 may be used to communicate image data from an image sensor of the camera module 202 to the packaged system 314 (e.g., a system on a chip (SOC)), for example, reception by the ISP 316 residing in/on or included within the packaged system 314. In some aspects, the ISP 316 may reside at another location away from the package system 314 and other electrical traces and other electrical connectors may be used to provide image data from the camera module 202 to the ISP 316 residing at another location away from the packaged system 314. The one or more camera electrical connections 208 (e.g., (ZIF) connection(s)) may electronically connect the camera module 202 (e.g., an image sensor of the camera module 202), via the one or more camera electrical traces 206 to the display PCB 302. The one or more device electrical traces 212 may be in electrical communication with the ISP 316 residing in the packaged system 314 via a packaged system electrical connection 313 and the display PCB 302 via the one or more device electrical connections 210. Thus, the camera module 202 (e.g., an image sensor of the camera module 202) may be in electronic communication with and communicate image data to the ISP 316 (e.g., residing in/on the packaged system 314) via the one or more camera electrical traces 206, the one or more camera electrical connections 208, the display PCB 302, the one or more device electrical connections 210, the one or more device electrical traces 212, and the one or more package system electrical connections 313. In some aspects, the electrical traces and/or the electrical connections described herein may include additional and/or dedicated traces and pins for communication of the image data.

As described herein, the camera module 202 may be integrated into an electronic device using the FC integration via the bracket 204 so the camera module 202 may be assembled into the FC or the display so that the camera module 202 may be calibrated and checked (e.g., functional checks) before and/or without being fully assembled with the electronic device. Also, with FC integration, positional tolerances of the camera module with respect to the display may be tight because the camera module may have to look through traces and light emitting diodes (LEDs) on the display. In some aspects, a curvature on the display may affect the camera module enhancing the need for tight positional tolerances of the camera module with respect to the display. It should be noted that due to the configuration of the camera module 202 and the bracket 204, a slightly smaller battery may be included in the electric device 100, an antenna module (not shown) may be reconfigured due to the loss in space within the housing 102. Also, when the ISP 316 is not included with the packaged system 314, an additional side car may be needed within the housing 102 occupying additional space to retain the ISP 316. In some aspects, the cutout 305 through the display PCB 302 may affect the near field communication (NFC) coil causing the NFC coil to jog around the cutout 305.

As shown in FIG. 4, the electronic device 100 includes the camera module 202, the bracket 204, the display PCB 302, the camera electrical trace(s) 206, the camera electrical connection(s) 208, the device electrical connection(s) 210, and the device electrical trace(s) 212. The camera module 202 and the bracket 204 occupy space on the display PCB 302. Accordingly, an ambient light sensor (ALS) 402 may be moved along the y-direction (e.g., further down the page) and reside in the location shown in FIG. 4. Similarly, the device electrical connection(s) 210 may be moved along the y-direction (e.g., further down the page) and reside in the location shown in FIG. 4. Also, as shown in FIG. 4, a battery profile 404 of a battery may occupy a large cross-sectional area of the electronic device 100.

As shown in FIG. 5, the electronic device 100 includes the display PCB 302 having the cutout 305 and the isolator 308 positioned on the display PCB 302 and surrounding the cutout 305. The electronic device 100 also includes the top bracket 204a and the bottom bracket 204b of the bracket 204. The top bracket 204a includes upper arms 501 for fastening the top bracket 204a to the display PCB 302 and includes a hole 503 for receiving at least a portion of the camera module 202. Due to the hole 503 receiving at least a portion of the camera module 202, the top bracket 204a surrounds the camera module 202 for retaining the camera module 202 in a fixed position in the x-direction and the y-direction. The top bracket 204a also includes lower arms 505 for coupling the top bracket 204a to the arms 507 of the lower bracket 204b. Protrusions 509 extending from the arms 507 of the bottom bracket 204b are received by cut-aways 511 through the lower arms 505 of the top bracket 204a to secure fasten the top bracket 204a with the bottom bracket 204a thereby retaining the camera module 202 in a fixed position. The bottom bracket 204 having the “U-shape” may retain the camera module 202 at a fixed position in the z-direction. In addition, due the “U-shape” of the bottom bracket 204, the circuit board 310 may also be retained at a fixed position in the z-direction while allowing the camera electrical trace(s) 206 to extend from the circuit board 310 (e.g., through an open end of the “U-shape”) and connect (e.g., physically connect, electrically connect) to the display PCB 302 via the camera electrical connection(s) 208. In some aspects, a damping structure 312 may be positioned between the bottom bracket 204b and the camera module 202 and dampen movement of the camera module 202 in the z-direction, for example, in response to a drop event. In some aspects, the damping structure 312 may include a foam pad, one or more springs, or a cushion.

As described herein, a camera module may be integrated into an electronic device using a housing-side integration. For example, a camera module may be fixedly attached to the housing of the electronic device and compressed against an alert bracket via a bracket so that the camera module resides at a fixed position within the electronic device. With housing-side integration, the camera module may be fixedly attached to a lower portion of the housing and move with the lower portion of the electronic device. Also, with housing-side integration, the electronic device may need to be fully assembled before calibration and functional checks on the camera module may be performed. In addition, with housing-side integration, positional tolerances of the camera module with respect to the display may be less tight than positional tolerances with FC integration. Thus, alignment of the camera module with the display may be less accurate. Further, with housing-side integration, camera module testing may be performed before the display is attached to the electronic device.

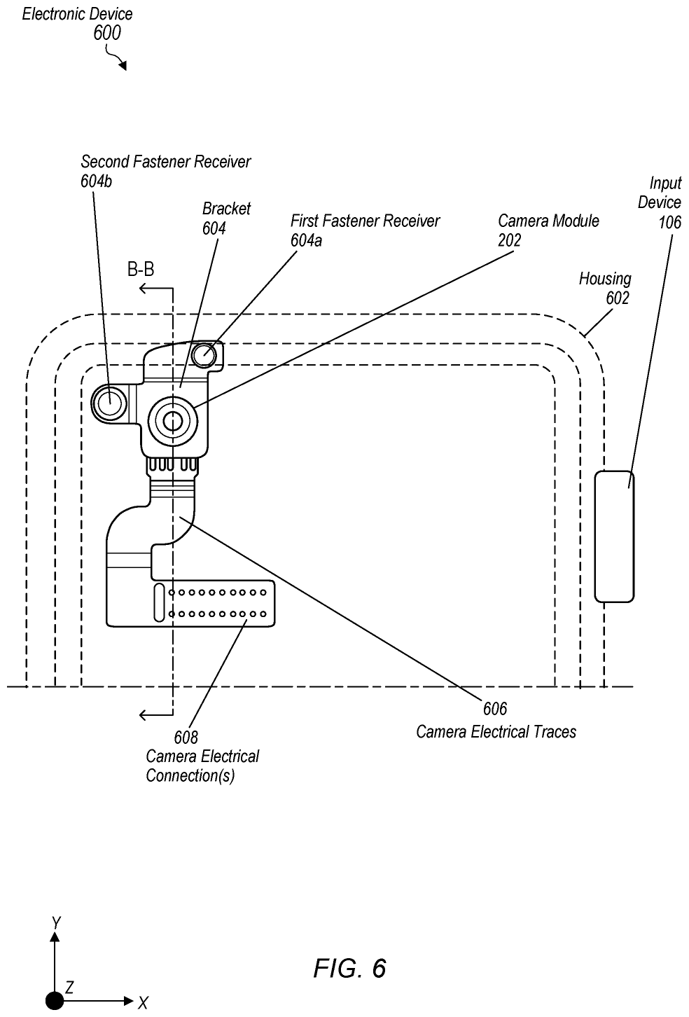

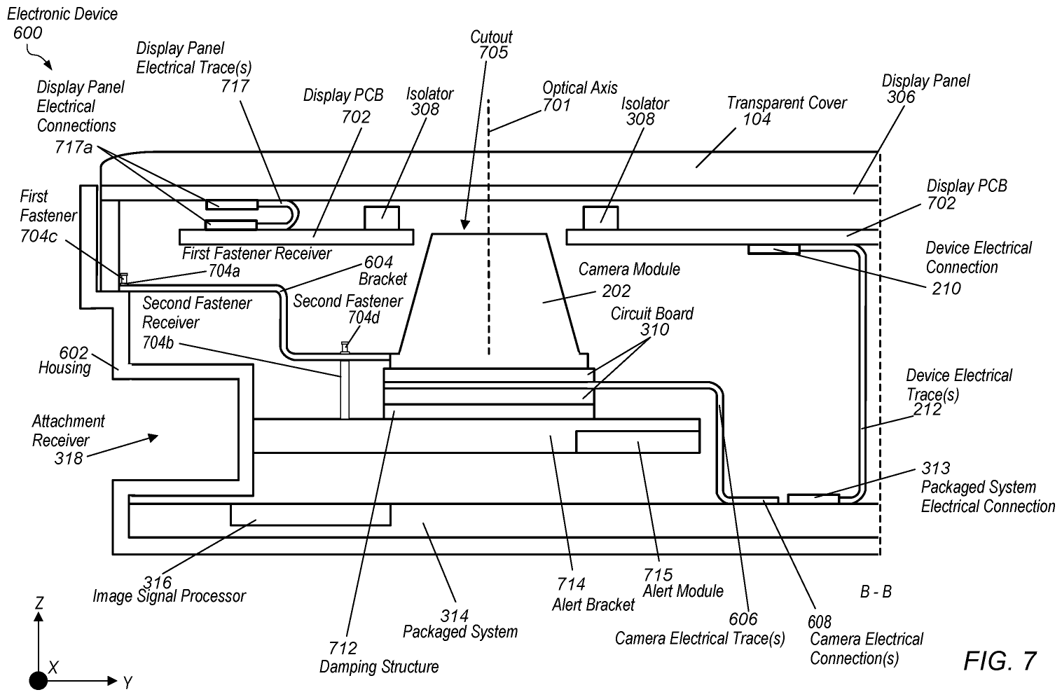

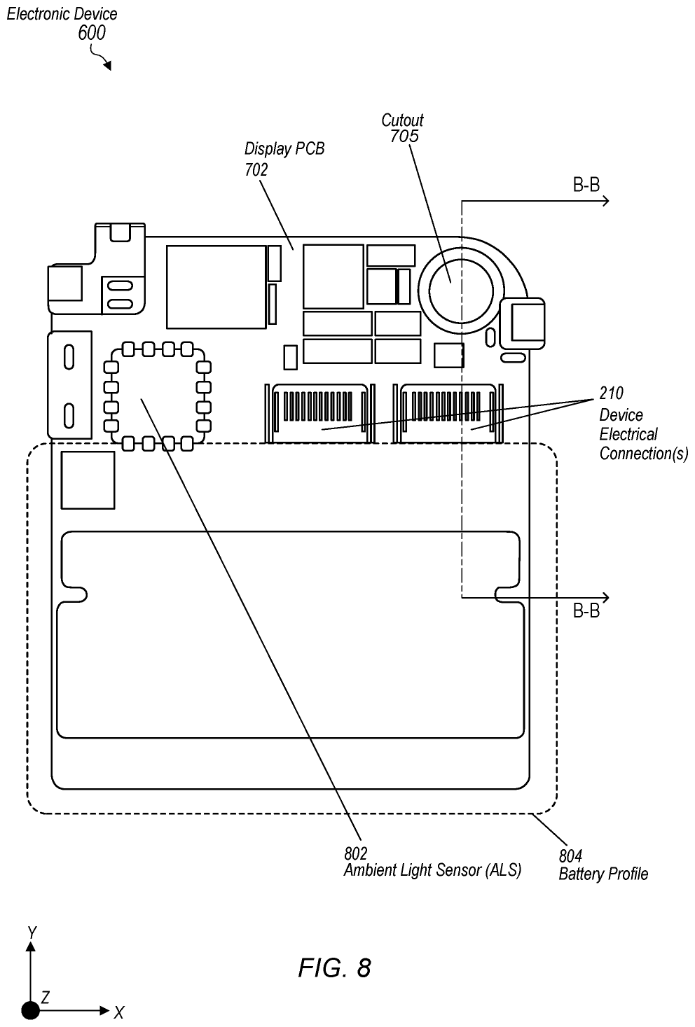

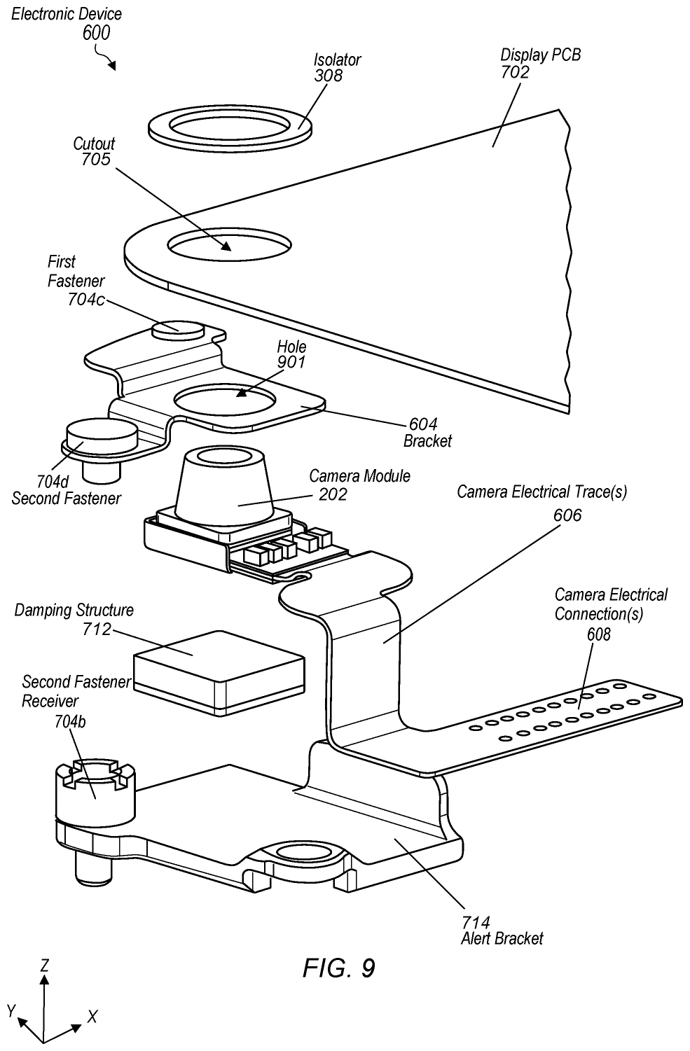

FIGS. 6, 7, 8, and 9 illustrate components to be used with a camera module 202 for housing-side integration of a camera module 202 into the electronic device 600, according to some embodiments. FIG. 6 shows an overhead view of at least some components of the electronic device 600. FIG. 7 shows a cross-sectional view of the electronic device 600 across the B-B plane. FIG. 8 shows an underneath view of at least some components of the electronic device 600 across the B-B plane. FIG. 9 shows an exploded view of at least some of the components of the electronic device 600. The electronic device 600 may include one or more same or similar features as the features described with respect to or illustrated in FIGS. 1, 2, 3, 4, 5, 10, 11, 12, 13, 14, 15, 16, 17, 18, 19, 20, 21, 22, 23, and 24. The example X-Y-Z coordinate system shown in FIGS. 6, 7, 8, and 9 may be used to discuss aspects of components and/or systems, and may apply to embodiments described throughout this disclosure. FIGS. 6, 7, 8, and 9, as with the other included figures, is shown for illustrative purposes and does not limit either the possible embodiments of the present invention or the claims.

As shown in FIG. 6, the electronic device 600 may include the camera module 202, a bracket 604, one or more camera electrical traces 606 attached to one or more camera electrical connections 608. The housing 602 may contain or house the camera module 202, the bracket 604, the one or more camera electrical traces 606, and the one or more camera electrical connections 608. In some aspects, the housing 602 may include an attachment receiver 318. The attachment receiver 318 may be configured to receive an attachment device for attaching the electronic device 600 to another object (e.g., an object external to or separate from the electronic device 600). For example, the attachment receiver 318 may be configured to receive a strap, a band, or a clamp for attaching the electronic device 600 to a body (e.g., a human body, an animal body), a stand, a hook, or a pole.

As described further herein, the bracket 604 may fixedly attach the camera module 202 a lower portion of the electronic device 600 (e.g., an interior surface within the electronic device 600). In some aspects, the lower portion of the electronic device 600 may include the housing 602 and components extending from the housing 602 and into an interior of the housing 602 (e.g., a speaker). In some aspects, the lower portion of the electronic device 600 may include components of the electronic device 602 that excludes display components (e.g., the transparent cover 104, the display panel 306, the display PCB 702, and the like). For example, the bracket 604 may fixedly attach the camera module 202 to an interior surface of the housing 602. As another example, the bracket 602 may fixedly attach the camera module 202 to a body extending from the interior surface of housing 602 and into an interior of the housing 602. In some aspects, the bracket 602 may fixedly attach the camera module 202 to the housing 602 via a first fastener 604a and to an alert bracket (e.g., the alert bracket 714 illustrated in FIG. 7) via a second fastener 604b. The alert bracket 714 may include an alert module (e.g., an alert module 715 illustrated in FIG. 7) and may extend from an interior surface of the housing 602 into an interior of the housing 602. The alert bracket 714 may include an alert module (e.g., an alert module 715 illustrated in FIG. 7) configured to provide a physical indication through the electronic device 600 that an event has occurred. For example, in response to determining that a battery of the electronic device 600 is below a threshold, an alert module residing in/on the alert bracket 714 may vibrate causing vibration of the entire electronic device 600. As another example, in response to determining that a battery of the electronic device 600 is fully charged, an alert module residing in/on the alert bracket 714 may emit a sound indicating that the electronic device 600 is fully charged. The alert bracket 714 may include one or more alert modules such as a vibration alert module, a speaker alert module, or the like.

The one or more camera electrical traces 506 may be used to communicate image data from an image sensor of the camera module 202 to a packaged system (e.g., the packaged system 314 illustrated in FIG. 7) (e.g., a system on a chip (SOC)), for example, an ISP (e.g., the ISP 316 illustrated in FIG. 7) residing in/on or included within the packaged system. As described further herein, the one or more camera electrical connections 608 (e.g., (ZIF) connection(s)) may electronically connect the camera module 202 (e.g., an image sensor of the camera module 202) directly to the packaged system (e.g., the ISP 316 of the packaged system 314). Thus, the camera module 202 (e.g., an image sensor of the camera module 202) may be in electronic communication with and communicate image data to the ISP (residing in the packaged system) via the one or more camera electrical traces 606 and the one or more camera electrical connections 608.

As shown in FIG. 7, and as described herein, the electronic device 600 may include the camera module 202, the bracket 604, and the one or more camera electrical traces 606 attached to the one or more camera electrical connections 608, and the alert bracket 714 including the alert module 715. The electronic device 600 may also include a display PCB 702, the display panel 306, and the transparent cover 104 residing over the display PCB 702 and the display panel 306. The display PCB 702 may be electrically connected to the display panel 306, via the display panel electrical trace(s) 317 and the display panel electrical connections 317a, and may be configured to command pixels on the display panel 306 to individually luminate a particular color and a particular brightness for image display. In some aspects, the display panel 306 may be an organic light emitting diode (OLED) display, a micro LED display, an liquid crystal display (LCD), or the like. As similarly described herein, the one or more device electrical traces 212 may be in electrical communication with the packaged system 314 (e.g., and the ISP 316 residing in the packaged system) via the packaged system electrical connection(s) 313 and the display PCB 702 via the one or more device electrical connections 210 to provide electronic communication between the display PCB 702 and the package system 314.

In some aspects, the bracket 604 may fixedly attach the camera module 202 to the housing 602 and the alert bracket 714. As shown in FIG. 3, the bracket 604 may include a first fastener receiver 704a and a second fastener receiver 704b. Through the first fastener receiver 704a, a first fastener 704c may fit through at least a portion of the housing 602 securing the bracket 604 to the housing 602 and fixedly attach the camera module 202 to the housing 602. Similarly, through the second fastener receiver 704b, a second fastener 704d may fit through at least a portion of the alert bracket 714 securing the bracket 604 to the alert bracket 714 and fixedly attach the camera module 202 to the alert bracket 714. As shown in FIG. 9, the bracket 604 may have a hole (e.g., a hole 901 illustrated in FIG. 9) for receiving the camera module 202 and retaining the camera module 202 in a fixed in the x-direction and the y-direction. The alert bracket 714 may be provide support for the camera module 202 and retain the camera module 202 in a fixed position along the optical axis 701 (e.g., in the z-direction). With the camera module 202 extending through the hole, a lower surface of the bracket 604 may press against an upper surface of the camera module 202 and exert a compression force on the camera module 202 towards the alert bracket 714 thereby securing the camera module 202 in a fixed position along the optical axis 701. Also, due to the bracket 604 engaging an upper surface of the camera module 202, the circuit board 310 may also be retained at a fixed position in the z-direction while allowing the camera electrical trace(s) 606 to extend from the circuit board 310 (e.g., below the bracket 604) and connect (e.g., physically connect, electrically connect) to the packaged system 314. In some aspects, a damping structure 712 positioned between the camera module 202 and the alert bracket 714 (e.g., between the circuit board 310 and the alert bracket 714) may dampen movement of the camera module 202 in the z-direction, for example, in response to a drop event. In some aspects, the damping structure 712 may include a foam pad, one or more springs, or a cushion.

As described herein, the bracket 604 retains the camera module 202 in a fixed position within the electronic device 600. The bracket 604 also aligns the camera module 202 with a cutout 705 extending through the display PCB 702 so that the cutout 705 is centered around the optical axis 701 of the camera module 202. With the cutout 705 aligned with the optical axis 701 of the camera module 202, the camera module 202 may be able to receive light through the display panel 306 to capture an image. In some aspects, the isolator 308 (e.g., ring) positioned on the display PCB 702 and surrounding the cutout 705 may be configured to isolate light from a volume between the display panel 306 and the camera module 202. In some aspects, the isolator 308 may also be configured to keep dust and particles away from the lens of the camera module 202. In some aspects, the camera module 202 may receive light through cutout 705 and the display panel 306 for image capture. In some aspects, the display PCB 702 may command an area of the display panel 306 over the camera module 202 to allow more light to pass through the display panel 306 so that the camera module 202 may capture an image. In some aspects, the display panel 306 may include a hole to allow light to pass through so that the camera module 202 may capture an image. In some aspects, the display panel 306 may include a small region aligned with the optical axis 301 and having a high transparency (e.g., relative to a remaining portion of the display panel 306 so that the camera module receives light for image capture.

The one or more camera electrical traces 606 may be used to communicate image data from an image sensor of the camera module 202 to the packaged system 314 (e.g., a system on a chip (SOC)), for example, reception by the ISP 316 residing in/on or included within the packaged system 314. In some aspects, the ISP 316 may reside at another location away from the package system 314 and other electrical traces and other electrical connectors may be used to provide image data from the camera module 202 to the ISP 316 residing at another location away from the packaged system 314. The one or more camera electrical connections 608 (e.g., (ZIF) connection(s)) may electronically connect the camera module 202 (e.g., an image sensor of the camera module 202), via the one or more camera electrical traces 606 directly to the package system 314 and/or the ISP 316. In some aspects, the electrical traces and/or the electrical connections described herein may include additional and/or dedicated traces and pins for communication of the image data.

As described herein, the camera module 202 may be integrated into an electronic device using the housing-side integration via the bracket 604, the housing 602, and the alert bracket 714 and fully assembled before calibration and functional checks on the camera module may be performed. In addition, with housing-side integration, positional tolerances of the camera module with respect to the display may be less tight than positional tolerances with FC integration. Thus, alignment of the camera module with the display may be less accurate. Further, with housing-side integration, camera module testing may be performed before the display is attached to the electronic device. It should be noted that due to the configuration of the camera module 202 and the bracket 604, a slightly smaller battery may be included in the electric device 600, an antenna module (not shown) may be reconfigured due to the loss in space within the housing 602. Also, when the ISP 316 is not included with the packaged system 314, an additional side car may be needed within the housing 602 occupying additional space to retain the ISP 316. In some aspects, the cutout 305 through the display PCB 302 may affect the near field communication (NFC) coil causing the NFC coil to jog around the cutout 305.

As shown in FIG. 8, the electronic device 600 includes the display PCB 702, the cutout 705, and the device electrical connection(s) 210. The cutout 705 may occupy space on the display PCB 702. Accordingly, an ambient light sensor (ALS) 802 may be moved along the y-direction (e.g., further down the page) and reside in the location shown in FIG. 8. Similarly, the device electrical connection(s) 210 may be moved along the y-direction (e.g., further down the page) and reside in the location shown in FIG. 8. Also, as shown in FIG. 8, a battery profile 804 of a battery may occupy a large cross-sectional area of the electronic device 600.

As shown in FIG. 9, the electronic device 600 includes the display PCB 702 having the cutout 705 and the isolator 308 positioned on the display PCB 702 and surrounding the cutout 705. The electronic device 600 also includes the bracket 604 having the first fastener receiver 704a (illustrated in FIG. 7), the first fastener 704c, the second fastener receiver 704b, and the second fastener 704d. Through the first fastener receiver 704a, a first fastener 704c may fit through at least a portion of the housing 602 securing the bracket 604 to the housing 602 and fixedly attach the camera module 202 to the housing 602. Similarly, through the second fastener receiver 704b, a second fastener 704d may fit through at least a portion of the alert bracket 714 securing the bracket 604 to the alert bracket 714 and fixedly attach the camera module 202 to the alert bracket 714.

As shown in FIG. 9, the bracket 604 may have a hole 901 for receiving the camera module 202 and retaining the camera module 202 in a fixed in the x-direction and the y-direction. The alert bracket 714 may be provide support for the camera module 202 and retain the camera module 202 in a fixed position along the optical axis 701 (e.g., in the z-direction). With the camera module 202 extending through the hole 901, a lower surface of the bracket 604 may press against an upper surface of the camera module 202 and exert a compression force on the camera module 202 towards the alert bracket 714 thereby securing the camera module 202 in a fixed position along the optical axis 701 (e.g., in the z-direction). Also, due to the bracket 604 engaging an upper surface of the camera module 202, the circuit board 310 may also be retained at a fixed position in the z-direction while allowing the camera electrical trace(s) 606 to extend from the circuit board 310 (e.g., below the bracket 604) and connect (e.g., physically connect, electrically connect) to the packaged system 314. In some aspects, a damping structure 712 positioned between the camera module 202 and the alert bracket 714 (e.g., between the circuit board 310 and the alert bracket 714) may dampen movement of the camera module 202 in the z-direction, for example, in response to a drop event. In some aspects, the damping structure 712 may include a foam pad, one or more springs, or a cushion.

As described herein, the bracket 604 retains the camera module 202 in a fixed position within the electronic device 600. The bracket 604 also aligns the camera module 202 with the cutout 705 extending through the display PCB 702 so that the cutout 705 is centered around the optical axis 701 of the camera module 202. With the cutout 705 aligned with the optical axis 701 of the camera module 202, the camera module 202 may be able to receive light through the display panel 306 to capture an image. In some aspects, the isolator 308 (e.g., ring) positioned on the display PCB 702 and surrounding the cutout 705 may be configured to isolate light from a volume between the display panel 306 and the camera module 202. In some aspects, the isolator 308 may also be configured to keep dust and particles away from the lens of the camera module 202. In some aspects, the camera module 202 may receive light through cutout 705 and the display panel 306 for image capture. In some aspects, the display PCB 702 may command an area of the display panel 306 over the camera module 202 to allow more light to pass through the display panel 306 so that the camera module 202 may capture an image. In some aspects, the display panel 306 may include a hole to allow light to pass through so that the camera module 202 may capture an image. In some aspects, the display panel 306 may include a small region aligned with the optical axis 301 and having a high transparency (e.g., relative to a remaining portion of the display panel 306 so that the camera module receives light for image capture.

The one or more camera electrical traces 606 may be used to communicate image data from an image sensor of the camera module 202 to the packaged system 314 (e.g., a system on a chip (SOC)), for example, reception by the ISP 316 residing in/on or included within the packaged system 314. In some aspects, the ISP 316 may reside at another location away from the package system 314 and other electrical traces and other electrical connectors may be used to provide image data from the camera module 202 to the ISP 316 residing at another location away from the packaged system 314. The one or more camera electrical connections 608 (e.g., (ZIF) connection(s)) may electronically connect the camera module 202 (e.g., an image sensor of the camera module 202), via the one or more camera electrical traces 606 directly to the package system 314 and/or the ISP 316. In some aspects, the electrical traces and/or the electrical connections described herein may include additional and/or dedicated traces and pins for communication of the image data.

As described herein, a camera module may be placed within a corner of the electronic device. The display in front of the camera module may optionally maintain emissive pixelation such that the camera module is hidden behind the display panel. In some aspects, the display region above the camera module may include removed pixelation such as a hole or notch in the display panel. In at least these configurations, the camera module may be positioned along a center axis of the electronic device for symmetrical aesthetics.

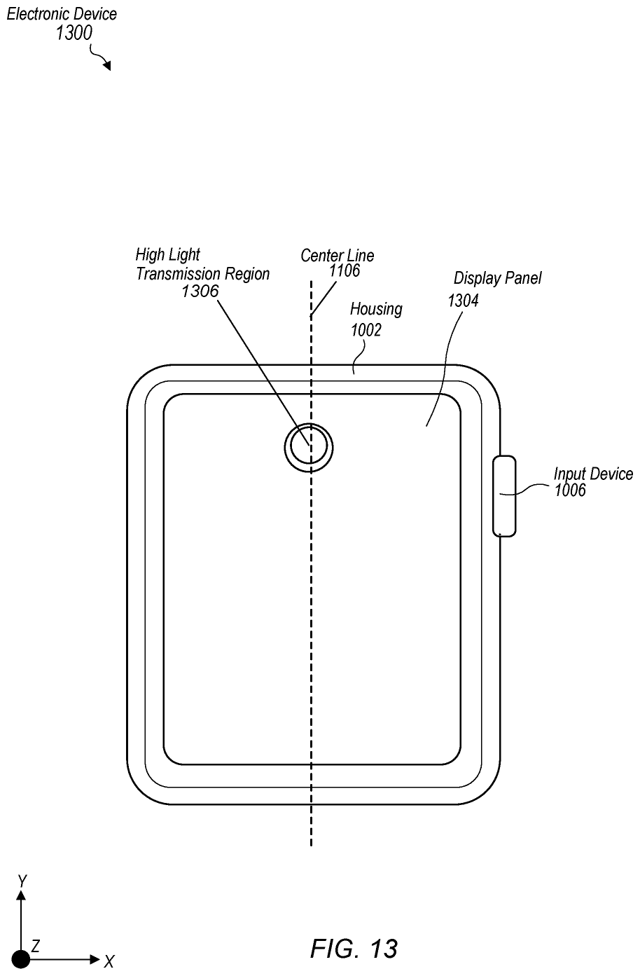

FIGS. 10, 11, 12, and 13 illustrate electronic device configurations, according to some embodiments. FIG. 10 shows a cross-sectional overhead view of a configuration of an electronic device 1000. FIG. 11 shows a cross-sectional overhead view of an electronic device 1100. FIG. 12 shows a cross-sectional overhead view of an electronic device 1200. FIG. 13 shows a cross-sectional overhead view of an electronic device 1300. The electronic device 1000 illustrated in FIG. 10, the electronic device 1100 illustrated in FIG. 11, the electronic device 1200 illustrated in FIG. 12, and the electronic device 1300 illustrated in FIG. 13 may include and/or incorporate one or more components from each and/or may include or incorporate one or more components or configurations of the electronic device 100 illustrated in FIGS. 1, 2, 3, 4, and 5 as well as the electronic device 600 illustrated in FIGS. 1, 6, 7, 8, and 9. In addition, the electronic device 1000 illustrated in FIG. 10, the electronic device 1100 illustrated in FIG. 11, the electronic device 1200 illustrated in FIG. 12, and the electronic device 1300 illustrated in FIG. 13 may include one or more same or similar features as the features described with respect to or illustrated in FIGS. 1, 2, 3, 4, 5, 6, 7, 8, 9, 14, 15, 16, 17, 18, 19, 20, 21, 22, 23, and 24. The example X-Y-Z coordinate system shown in FIGS. 10, 11, 12, and 13 may be used to discuss aspects of components and/or systems, and may apply to embodiments described throughout this disclosure. FIGS. 10, 11, 12, and 13, as with the other included figures, is shown for illustrative purposes and does not limit either the possible embodiments of the present invention or the claims.

As shown in FIG. 10, the electronic device 1000 may include a housing 1002, an input device 1006, a battery 1004, and an alert bracket 1014. The battery 1004 and the alert bracket 1014 may be positioned so that both the battery 1004 and the alert bracket 1014 are bifurcated by a center line 1006 of the electronic device. In some aspects, the electronic device 1000 may not include a camera module allowing for greater tolerances for including the battery 1004 and the alert bracket 1014. As shown in FIG. 11, the electronic device 1100 may include the housing 1002 and the input device 1006. The electronic device 1100 may also include a camera module 1102 (which may be the same as or at least similar to the camera module 202 illustrated in FIGS. 2, 3, 4, 5, 6, 7, 8, and 9), a battery 1104, and an alert bracket 1114. Due to space occupied by the camera module 1102, the battery 1104 and/or the alert bracket 1114 may be smaller and/or have a different configuration compared to the battery 1004 and/or the alert bracket 1014 illustrated in FIG. 10. For example, the alert bracket 1114 may have an L-shape configuration compared to a more rectangular configure of the alert bracket 1014 and/or may be smaller in the x-direction and larger in the y-direction compared to the alert bracket 1014. The camera module 1102 may include an optical axis 1103. The optical axis 1103, the battery 1104, and the alert bracket 1114 may be positioned on the center line 1106 so that the battery 1104, the alert bracket 1114, and the camera module 1102 (e.g., the optical axis 1103) are bifurcated by a center line 1106 of the electronic device 1100. Because a display region above the camera module 1102 may include removed pixelation such as a hole or notch in the display panel and/or a different coloring compared to the rest of the display panel, the camera module 1102 (e.g., the optical axis 1104 of the camera module 1102) may be positioned along the center line 1106 of the electronic device 1100 for symmetrical aesthetics.

As shown in FIG. 12, the electronic device 1200 may include the housing 1002, the input device 1006, and the camera module 1102. The electronic device 1200 may also include a battery 1204 and an alert bracket 1214. Due to space occupied by the camera module 1102, the battery 1204 and/or the alert bracket 1214 may be smaller and/or have a different configuration compared to the battery 1004 and/or the alert bracket 1014 illustrated in FIG. 10. For example, the alert bracket 1214 may have an L-shape configuration compared to a more rectangular configure of the alert bracket 1014 and/or may be smaller in the x-direction and larger in the y-direction compared to the alert bracket 1014. The camera module 1102 may include the optical axis 1103. The battery 1204 and the alert bracket 1214 may be rotated 90 degrees compared to the battery 1104 and the alert bracket 1114 so that the battery 1204 and the alert bracket 1214 are not bifurcated by the center line 1106 of the electronic device 1200. However, because a display region above the camera module 1102 may include removed pixelation such as a hole or notch in the display panel and/or a different coloring compared to the rest of the display panel, the camera module 1102 (e.g., the optical axis 1104 of the camera module 1102) may be positioned along the center line 1106 of the electronic device 1100 for symmetrical aesthetics.

As shown in FIG. 13, the electronic device 1300 may include the housing 1002 and the input device 1006. The electronic device 1300 may also include a display panel 1304 (as described herein) including a high light transmission region region 1306 extending through the display panel 1304 and along the center line 1106. A camera module (e.g., the camera module 1102 illustrated in FIGS. 11 and 12) may be positioned along the center line 1106 beneath of the high light transmission region 1306 of the display panel 1304 so that the high light transmission region 1306 is aligned with the optical axis. The high light transmission region 1306 may include removed pixelation such as a hole or notch through the display panel 1304 and/or a different coloring compared to the rest of the display panel 1304, and positioned along the center line 1106 of the electronic device 1300 for symmetrical aesthetics.

As described herein, an electronic device may include a camera module positioned behind an emissive display hiding the camera module to attain improved aesthetics and for better fit and configurations. Some display panels may be very opaque allowing little light to pass therethrough to the camera module. As described above, a display panel may include a high light transmission region (e.g., an enhanced light transmission region) for increasing light transmission to the camera module without compromising the entire display panel. The high light transmission region may include a hole punch through the display panel (e.g., a pin-hole sized hole punch), a notch, or a region with low pixel count or routing density. The size of the high light transmission region may depend on several camera module parameters including field-of-view, entrance pupil size and position, lens barrel dimensions, F number, and the like. The high light transmission region may be co-designed with the camera module parameters to enable a smaller high light transmission region and better camera module performance. For example, the high light transmission region may be co-designed with the camera module parameters to achieve a smallest possible high light transmission region without sacrificing and/or changing camera module designs and/or performance.

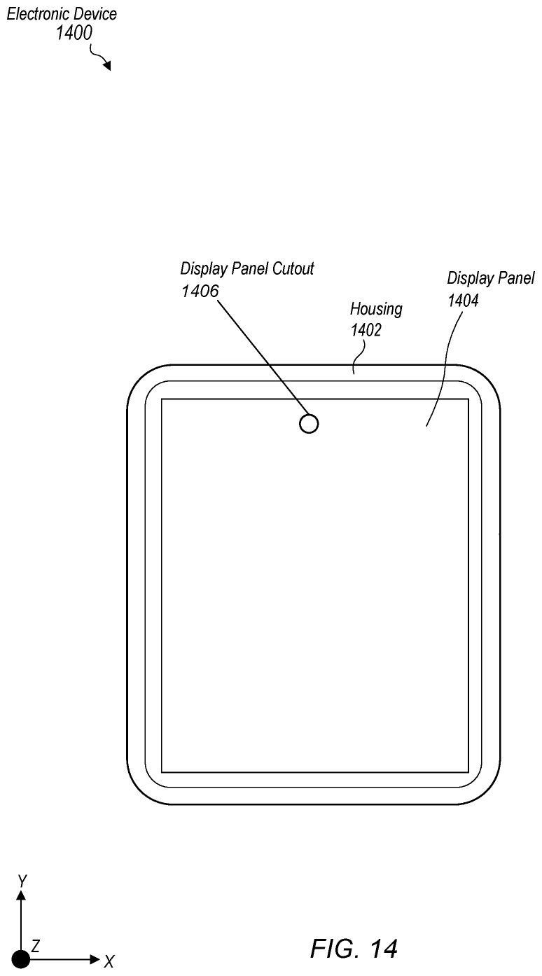

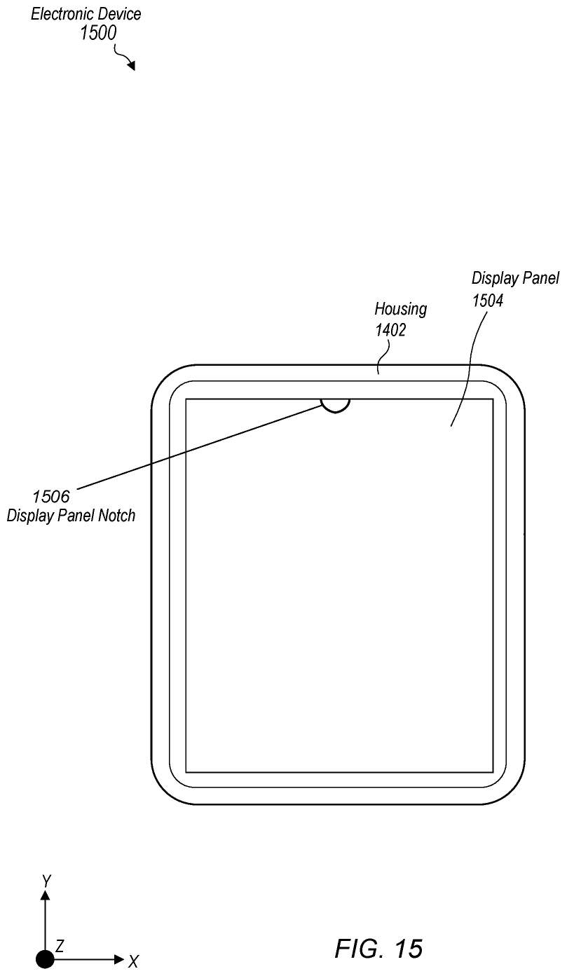

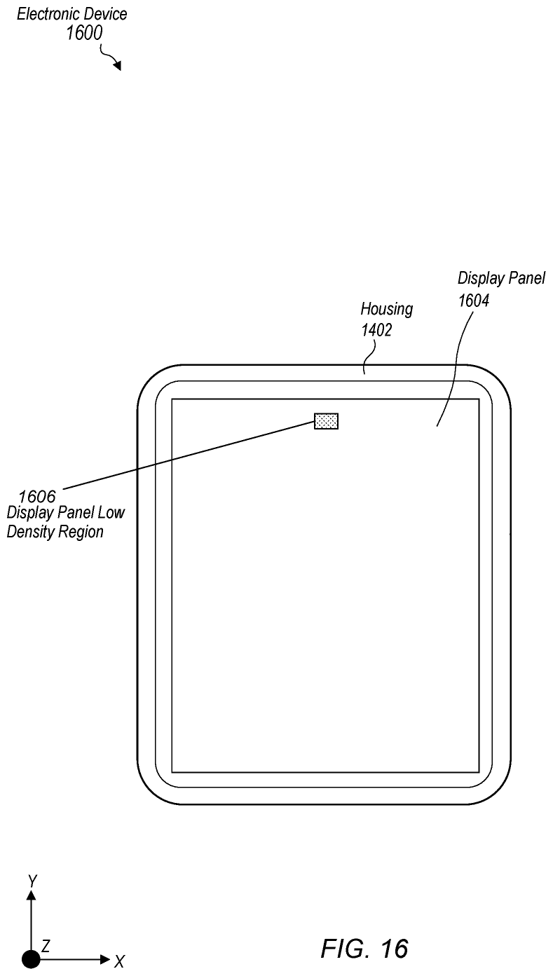

As described herein, a display panel may include a high light transmission region for increasing light transmission to the camera module positioned behind the display panel without compromising the entire display panel. The high light transmission region may include a hole punch through the display panel (e.g., a pin-hole sized hole punch), a notch, or a region with low pixel count or routing density. FIGS. 14, 15, and 16 illustrate electronic device configurations, according to some embodiments. FIG. 14 shows a cross-sectional overhead view of a configuration of an electronic device 1400. FIG. 15 shows a cross-sectional overhead view of an electronic device 1500. FIG. 16 shows a cross-sectional overhead view of an electronic device 1600. The electronic device 1400 illustrated in FIG. 14, the electronic device 1500 illustrated in FIG. 15, and the electronic device 1600 illustrated in FIG. 16 may include and/or incorporate one or more components from each and/or may include or incorporate one or more components or configurations of the electronic device 100 illustrated in FIGS. 1, 2, 3, 4, and 5, the electronic device 600 illustrated in FIGS. 1, 6, 7, 8, and 9, the electronic device 1000 illustrated in FIG. 10, the electronic device 1100 illustrated in FIG. 11, the electronic device 1200 illustrated in FIG. 12, and the electronic device 1300 illustrated in FIG. 13. In addition, the electronic device 1400 illustrated in FIG. 14, the electronic device 1500 illustrated in FIG. 15, and the electronic device 1600 illustrated in FIG. 16 may include one or more same or similar features as the features described with respect to or illustrated in FIGS. 1, 2, 3, 4, 5, 6, 7, 8, 9, 10, 11, 12, 13, 17, 18, 19, 20, 21, 22, 23, and 24. The example X-Y-Z coordinate system shown in FIGS. 14, 15, and 16 may be used to discuss aspects of components and/or systems, and may apply to embodiments described throughout this disclosure. FIGS. 14, 15, and 16, as with the other included figures, is shown for illustrative purposes and does not limit either the possible embodiments of the present invention or the claims.

As shown in FIG. 14, the electronic device 1400 may include a housing 1402, a display panel 1404, and a display region cutout 1406. The display region cutout 1406 may be a high light transmission region. The display region cutout 1406 may have a circular shape to match a circular shape of one or more lenses of the camera module. A camera module may be positioned behind the display panel 1404 and directly beneath the display region cutout 1406. The display region cutout 1406 may permit between 50% and 100% of light received by the display panel to pass through to the camera module compared to the remaining display panel 1404 which may allow only about 0.15% of light received to pass therethrough.

As shown in FIG. 15, the electronic device 1500 may include the housing 1402, a display panel 1504, and a display region notch 1506. The display region notch 1506 may be a high light transmission region. A camera module may be positioned behind the display panel 1404 and beneath the display region notch 1506. The display region notch 1506 may be positioned along an edge of the display panel 1504 for aesthetics. The display region notch 1406 may permit between 50% and 100% of light received by the display panel to pass through to the camera module compared to the remaining display panel 1504 which may allow only about 0.15% of light received to pass therethrough.

As shown in FIG. 16, the electronic device 1600 may include the housing 1402, a display panel 1604, and a display panel low density region 1606. The display panel low density region 1606 may be a high light transmission region. A camera module may be positioned behind the display panel 1404 and directly beneath the display panel low density region 1606. In some aspects, the display panel 1604 may be an OLED display panel. When the display panel 1604 is an OLED display panel, a density of the pixels at the display panel low density region 1606 may be reduced to increase light transmission through the display panel low density region 1606. In some aspects, the display panel 1604 may be a micro LED display panel. When the display panel 1604 is micro LED display panel, the display panel low density region 1606 may maintain a lower pixel density for the limited space of the display panel low density region 1606 and reroute connections and drivers to permit an increase in light through the display panel 1604. In some aspect, the display panel 1604 may be a liquid crystal display (LDC). When the display panel 1604 is an LCD, pixels may be activated or deactivated to change a size and/or a shape of the display panel low density region 1606. As such, parameters of the camera module such as F number (described further herein) may be changed, modified, and/or adjusted as the size and/or the shape of the display panel low density region 1606 changes. The display panel low density region 1606 may permit between 10% and 15% of light received by the display panel to pass through to the camera module compared to the remaining display panel 1504 which may allow only about 0.15% of light received to pass therethrough. In some aspects, a camera module (e.g., for performing machine vision image capture) may need about 10% of light received by the display panel 1604 to adequately capture an image (e.g., for machine vision image capturing).

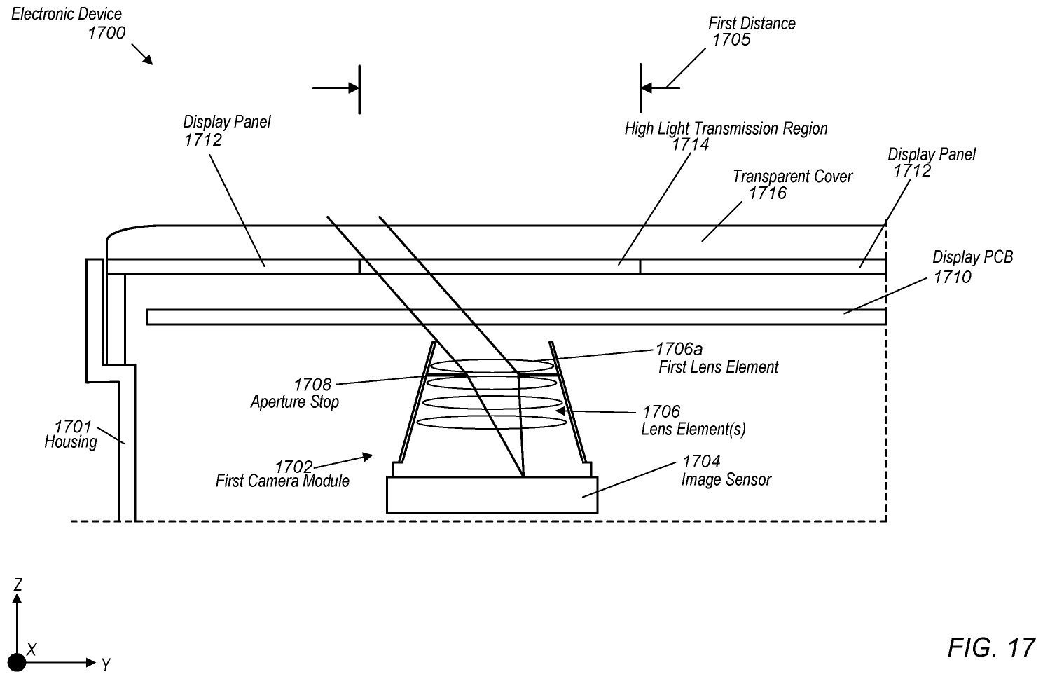

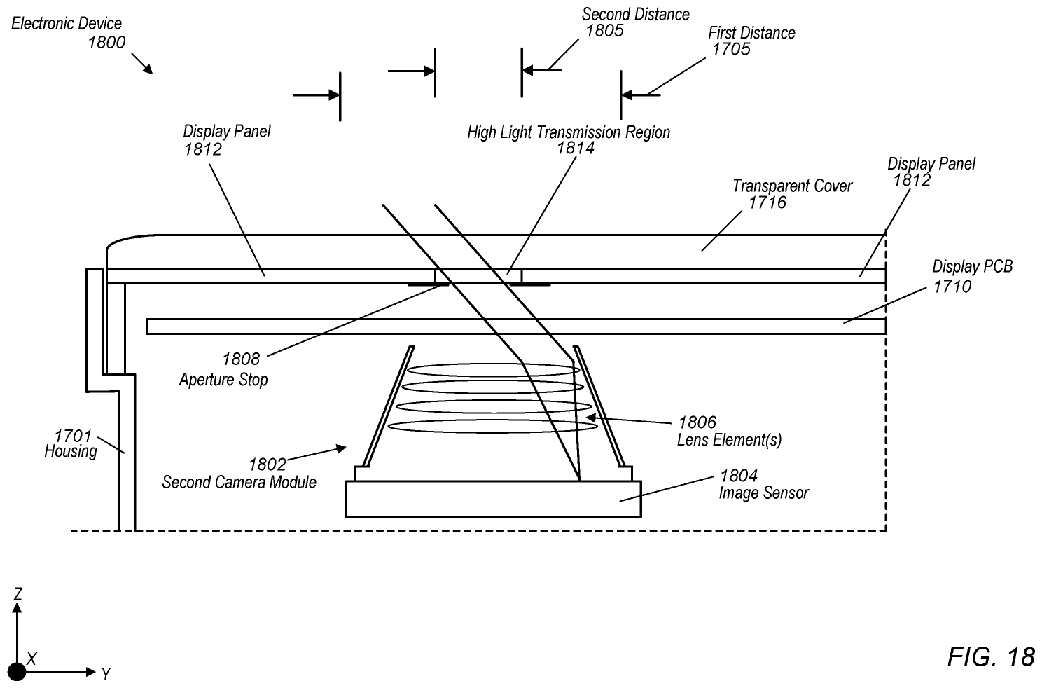

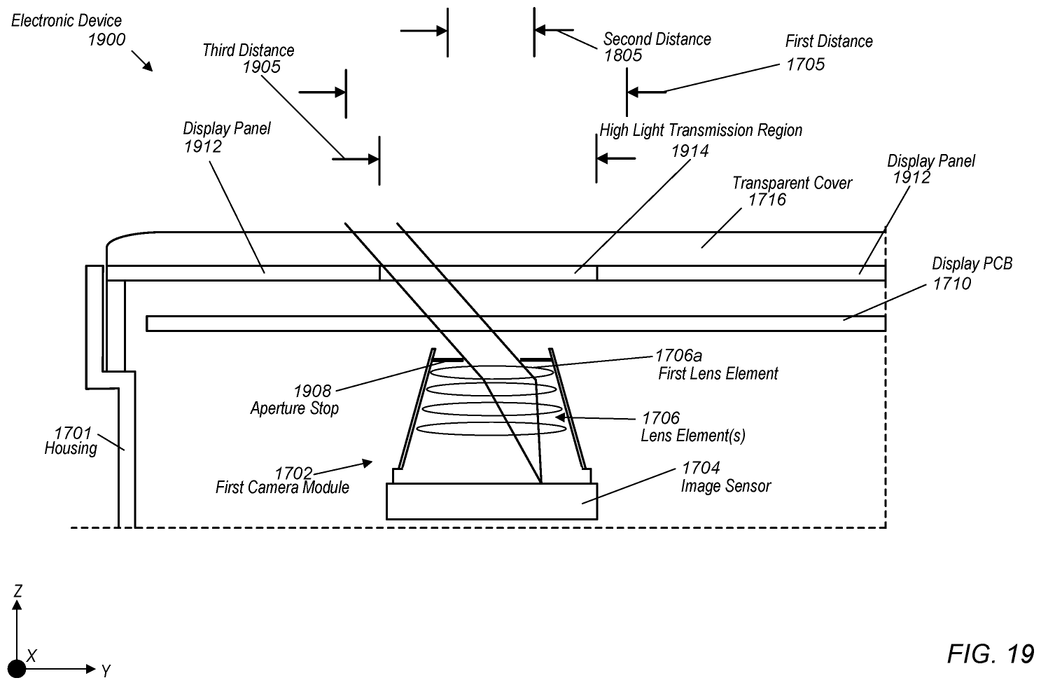

For at least some camera modules and for a given field-of-view and aperture size, a position of an aperture stop relative to the lenses may affect a size of the display region and thus a size of the high light transmission region. FIGS. 17, 18, and 19 illustrate electronic device configurations, according to some embodiments. FIG. 17 shows a cross-sectional view of a configuration of an electronic device 1700. FIG. 18 shows a cross-sectional view of an electronic device 1800. FIG. 19 shows a cross-sectional view of an electronic device 1900. The electronic device 1700 illustrated in FIG. 17, the electronic device 1800 illustrated in FIG. 18, and the electronic device 1900 illustrated in FIG. 19 may include and/or incorporate one or more components from each and/or may include or incorporate one or more components or configurations of the electronic device 100 illustrated in FIGS. 1, 2, 3, 4, and 5, the electronic device 600 illustrated in FIGS. 1, 6, 7, 8, and 9, the electronic device 1000 illustrated in FIG. 10, the electronic device 1100 illustrated in FIG. 11, electronic device 1200 illustrated in FIG. 12, the electronic device 1300 illustrated in FIG. 13, the electronic device 1400 illustrated in FIG. 14, the electronic device 1500 illustrated in FIG. 15, and electronic device 1600 illustrated in FIG. 16. In addition, the electronic device 1700 illustrated in FIG. 17, the electronic device 1800 illustrated in FIG. 18, and the electronic device 1900 illustrated in FIG. 19 may include one or more same or similar features as the features described with respect to or illustrated in FIGS. 1, 2, 3, 4, 5, 6, 7, 8, 9, 10, 11, 12, 13, 14, 15, 16, 20, 21, 22, 23, and 24. The example X-Y-Z coordinate system shown in FIGS. 17, 18, and 19 may be used to discuss aspects of components and/or systems, and may apply to embodiments described throughout this disclosure. FIGS. 17, 18, and 19, as with the other included figures, is shown for illustrative purposes and does not limit either the possible embodiments of the present invention or the claims.

As shown in FIG. 17, the electronic device 1700 may include a housing 1701, a transparent cover 1716, a display panel 1712 including a high light transmission region 1714, and a first camera module 1702. The high light transmission region 1714 may be the same as or at least similar to the high light transmission regions provided in FIGS. 14, 15, and/or 16. The first camera module 1702 may include an image sensor 1704, a plurality of lens elements 1706, and an aperture stop 1708. The first camera module 1702 (e.g., the lens elements 1706) may have a first size and/or level performance. The plurality of lens elements 1706 may include a first lens element 1706a position at the top of the lens element stack closest to the display panel 1712. As shown in FIG. 17, the aperture stop 1708 may be positioned directly beneath the first lens element 1706a within the stack of lens. Due to the position of the aperture stop 1708 and the size of the first camera module 1702, the marginal light rays extending from the image sensor 1702, through the first lens element 1706a, up through the high light transmission region 1714; creates a large light cone and may need a high light transmission region 1714 with a first distance 1705 (e.g., a diameter).

As shown in FIG. 18, the electronic device 1800 may include a housing 1701, a transparent cover 1716, a display panel 1812 including a high light transmission region 1814, and a second camera module 1802. The high light transmission region 1814 may be the same as or at least similar to the high light transmission regions provided in FIGS. 14, 15, and/or 16. An aperture stop 1808 may be positioned on the display panel 1812 and overlapping with at least a portion of the high light transmission region 1814. The second camera module 1802 may include an image sensor 1804, a plurality of lens elements 1806. The second camera module 1802 (e.g., the lens elements 1806) may have a second size and/or level performance that is/are larger than and/or greater than a size and/or a performance another camera module (e.g., the first camera module 1702 illustrated in FIG. 17, the lens elements 1706 illustrated in FIG. 17). Due to the position of the aperture stop 1808, the marginal light rays extending from the image sensor 1804, through the lens elements 1806, through the aperture stop 1808, and up through the high light transmission region 1814; creates a small light cone and may use a high light transmission region 1814 with a second distance 1805 (e.g., a diameter) that is smaller than the first distance 1705 of the high light transmission region 1714. With the comparatively smaller second distance 1805 (e.g., diameter) of the high light transmission region 1814, less of the display panel 1812 may be obstructed for displaying images. However, the size of the second camera module 1802 (e.g., a size of the lens elements 1806 of the second camera module 1802) may be greater than the size of the first camera module 1802 (e.g., the size of the lens elements 1706 of the first camera module 1702) to accommodate the greater distance between entrance pupil formed by the aperture stop 1808 and the lens elements 1806 compared to the distance between aperture stop 1708 and the lens elements 1706 illustrated in FIG. 17. The larger second camera module 1802 (and larger lens elements 1806) may create tolerances with the electronic device 1800 that are too small and/or that may prevent other components for placement within the electronic device 1800 from fitting and/or operating properly.

As shown in FIG. 19, the electronic device 1900 may include the housing 1701, the transparent cover 1716, a display panel 1912 including a high light transmission region 1914, and a third camera module 1902. The high light transmission region 1914 may be the same as or at least similar to the high light transmission regions provided in FIGS. 14, 15, and/or 16. The third camera module 1902 may include the image sensor 1704, the plurality of lens elements 1706, and an aperture stop 1908. The third camera module 1702 may have a same or similar size and/or level of performance as the first camera module 1702 illustrated in FIG. 17. The plurality of lens elements 1706 may include the first lens element 1706a position at the top of the lens element stack closest to the display panel 1912. As shown in FIG. 19, the aperture stop 1908 may be positioned directly over the first lens element 1706a and over the stack of lens. Due to the position of the aperture stop 1908, the marginal light rays extending from the image sensor 1904, through the lens elements 1906, through the aperture stop 1908, and up through the high light transmission region 1914 creates a moderately sized light cone and may use the high light transmission region 1914 with a third distance 1905 (e.g., a diameter) that is larger than the first distance 1705 of the high light transmission region 1714 and smaller than the second distance 1805 of the high light transmission region 1814. With the comparatively moderate third distance 1905 (e.g., diameter) of the high light transmission region 1914, a moderate amount of the display panel 1912 may be obstructed from displaying images. However, the size of the third camera module 1902 (e.g., a size of the lens elements 1706 of the second camera module 1802) may be same size as the size of the first camera module 1702 (e.g., the lens elements 1706) while accommodating the greater distance between entrance pupil formed by the aperture stop 1908 and the lens elements 1706 compared to the distance between aperture stop 1708 and the lens elements 1706 as illustrated in FIG. 17. Thus, with the aperture stop 1908 being positioned between the plurality of lens 1706 and the high light transmission region 1914 (e.g., not abutting the display panel 1912), the third camera module 1902 (e.g., the lens elements 1706) may maintain a size and configuration for acceptable tolerances with the electronic device 1900 to allow functional and aesthetically acceptable positioning of the camera module 1902 within the electronic device 1900 and may allow other components for placement within the electronic device 1900 for proper performing proper operations.

The configurations described herein may minimize the camera module size (e.g., a size of the lens elements 1706) and a display region (e.g., the size or distance across the high light transmission region (e.g., the high light transmission region 1914) when the aperture stop (and thus the entrance pupil) is positioned between the lens and the high light transmission region. These minimizations may depend on several camera module parameters including field-of-view, entrance pupil size and position, lens barrel dimensions, F number, local length, and the like. It should be understood that the field of view may be the extent of the observable world that is seen at any given moment through the camera module. The field of view may be characterized by degrees. It should also be understood that the F value or F number may be a ratio of the camera module focal length to the diameter of the entrance pupil. It should further be understood that focal length may be a distance of a lens or mirror of the camera module to its focal point.

As described herein, to minimize the camera module size (e.g., a size of the lens elements 1706) and a display region (e.g., the size or distance across the high light transmission region (e.g., the high light transmission region 1914), the aperture stop (and thus the entrance pupil) may be positioned between the lens and the high light transmission region. In some aspects, a camera module may utilize an injection molded lens optics package with a unibody lens barrel. In some aspects, a camera module may utilize a wafer-level optics lens package that does not require a unibody lens barrel. As described herein, the closer the lens may be positioned to the display surface, the smaller the display region (and thus the high light transmission region) may be.

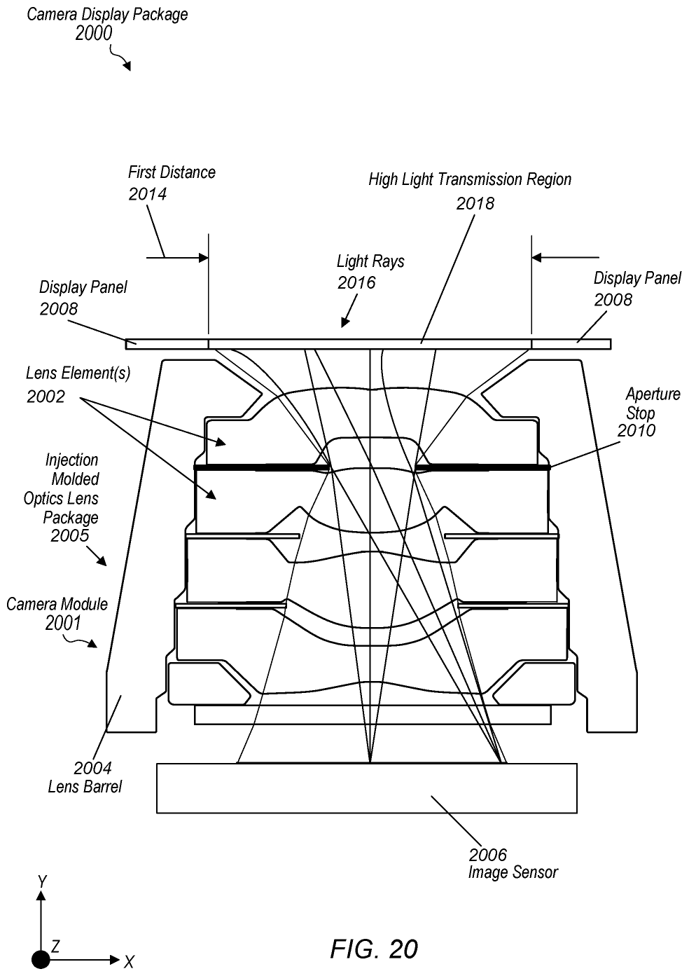

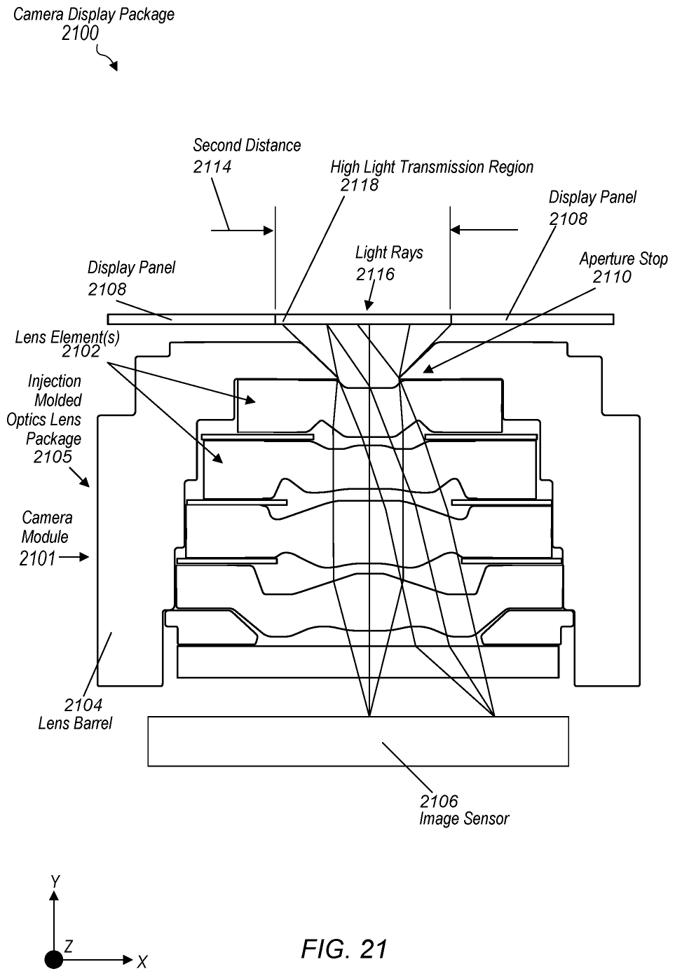

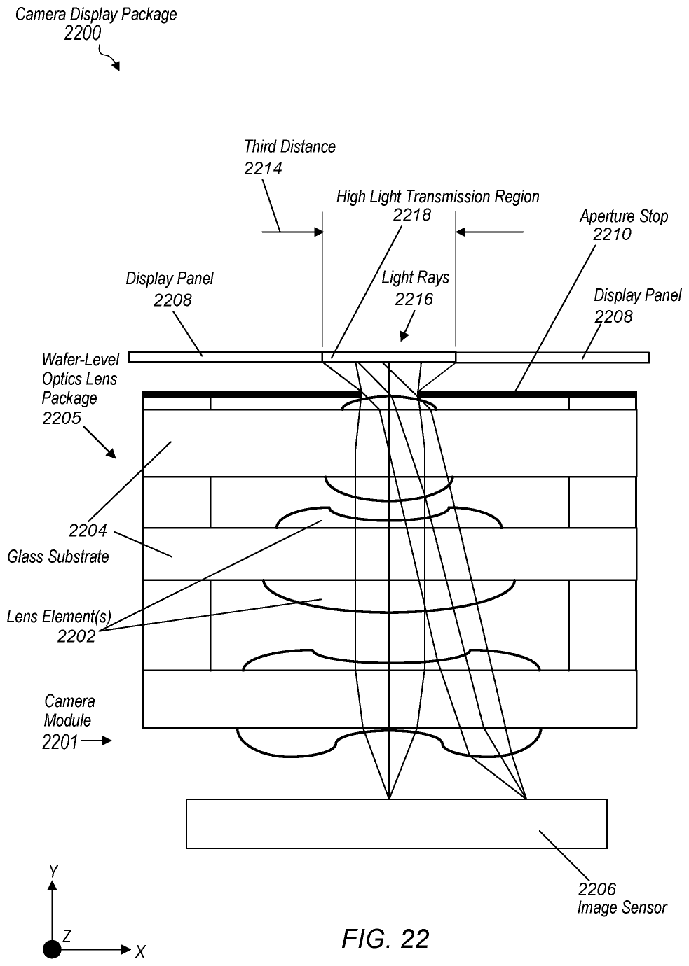

FIGS. 20, 21, and 22 illustrate camera display packages, according to some embodiments. FIG. 20 shows a cross-sectional view of a camera display package 2000. FIG. 21 shows a cross-sectional view of a camera display package 2100. FIG. 22 shows a cross-sectional view of a camera display package 2200. The camera display package 2000 illustrated in FIG. 20, the camera display package 2100 illustrated in FIG. 21, and the camera display package 2200 illustrated in FIG. 22 may include and/or incorporate one or more components from each and/or may include or incorporate one or more components or configurations of the electronic device 100 illustrated in FIGS. 1, 2, 3, 4, and 5, the electronic device 600 illustrated in FIGS. 1, 6, 7, 8, and 9, the electronic device 1000 illustrated in FIG. 10, the electronic device 1100 illustrated in FIG. 11, electronic device 1200 illustrated in FIG. 12, the electronic device 1300 illustrated in FIG. 13, the electronic device 1400 illustrated in FIG. 14, the electronic device 1500 illustrated in FIG. 15, the electronic device 1600 illustrated in FIG. 16, the electronic device 1700 illustrated in FIG. 17, the electronic device 1800 illustrated in FIG. 18, and the electronic device 1900 illustrated in FIG. 19. In addition, the camera display package 2000 illustrated in FIG. 20, the camera display package 2100 illustrated in FIG. 21, and the camera display package 2200 illustrated in FIG. 22 may include one or more same or similar features as the features described with respect to or illustrated in FIGS. 1, 2, 3, 4, 5, 6, 7, 8, 9, 10, 11, 12, 13, 14, 15, 16, 17, 18, 19, 23, and 24. The example X-Y-Z coordinate system shown in FIGS. 20, 21, and 22 may be used to discuss aspects of components and/or systems, and may apply to embodiments described throughout this disclosure. FIGS. 20, 21, and 22, as with the other included figures, is shown for illustrative purposes and does not limit either the possible embodiments of the present invention or the claims.

As shown in FIG. 20, the camera display package 2000 may include a camera module 2001 and a display panel 2008. The camera module 2001 may utilize an injection molded lens optics package 2005 including a plurality of lens elements 2002 and a lens barrel 2004, and an image sensor 2006. The camera module 2001 may also include an aperture stop 2010 positioned between the top two lens elements 2002 (e.g., the two lens elements 2002 that are closest to the display panel 2008. Due to the lens barrel 2004 and the top lens element, a distance is formed between the entrance pupil formed by the aperture stop 2010 and the display panel 2008. As a result, a light cone formed by the light right rays 2016 may utilize a first distance 2014 forming a diameter across the high light transmission region 2018. In some aspects, the first distance 2014 may be a greater distance than other distances described herein.

As shown in FIG. 21, the camera display package 2100 may include a camera module 2101 and a display panel 2108. Like the camera module 2001 illustrated in FIG. 20, the camera module 2101 may utilize an injection molded lens optics package 2105 including a plurality of lens elements 2102 and a lens barrel 2104, and an image sensor 2106. The camera module 2101 may also include an aperture stop 2110 (e.g., formed by the lens barrel 2104 or positioned adjacent the lens barrel 2104) positioned between the stack of lens elements 2102 (e.g., above the top lens element closest to the display panel 2108) and the display panel 2108. Due to a thickness of the lens barrel 2104, a distance is formed between the entrance pupil formed by the aperture stop 2110 and the display panel 2108. As a result, a light cone formed by the light right rays 2116 may utilize a second distance 2114 forming a diameter across the high light transmission region 2118. In some aspects, the second distance may be less than the first distance 2014 enabling a smaller high light transmission region 2118 on the display panel 2108 compared to the high light transmission region 2018 on the display panel 2008 illustrated in FIG. 20.

As shown in FIG. 22, the camera display package 2200 may include a camera module 2201 and a display panel 2208. The camera module 2201 may utilize a wafer-level optics lens package 2205 that does not require a unibody lens barrel, and an image sensor 2106. The wafer-level optics lens package 2205 may include glass substrates 2204 with lens elements 2202 formed on top and bottom surfaces of the glass substrates 2204. The camera module 2101 may also include an image sensor 2206 and an aperture stop 2210. The aperture stop 2210 may be positioned between the stack of lens elements 2202 (e.g., above the top lens element closest to the display panel 2208) and the display panel 2008. Because the wafer-level optics package 2205 does not include a lens barrel, a distance between the entrance pupil formed by the aperture stop 2210 and the display panel 2208 may be less compared to the injection molded lens optics packages 2005 and 2105. The display region or high light transmission region 2218 may be the aperture of the camera module 2201. In other words, the aperture of the camera module 2201 may be part of the display region or high light transmission region 2218. As a result, a light cone formed by the light right rays 2216 may utilize a third distance 2214 forming a diameter across the high light transmission region 2218. In some aspects, the third distance may be less than the first distance 2014 and the second distance 2114 enabling a smaller high light transmission region 2118 on the display panel 2208 compared to the high light transmission region 2018 on the display panel 2008 illustrated in FIG. 20 and compared to the high light transmission region 2118 on the display panel 2108 illustrated in FIG. 21.

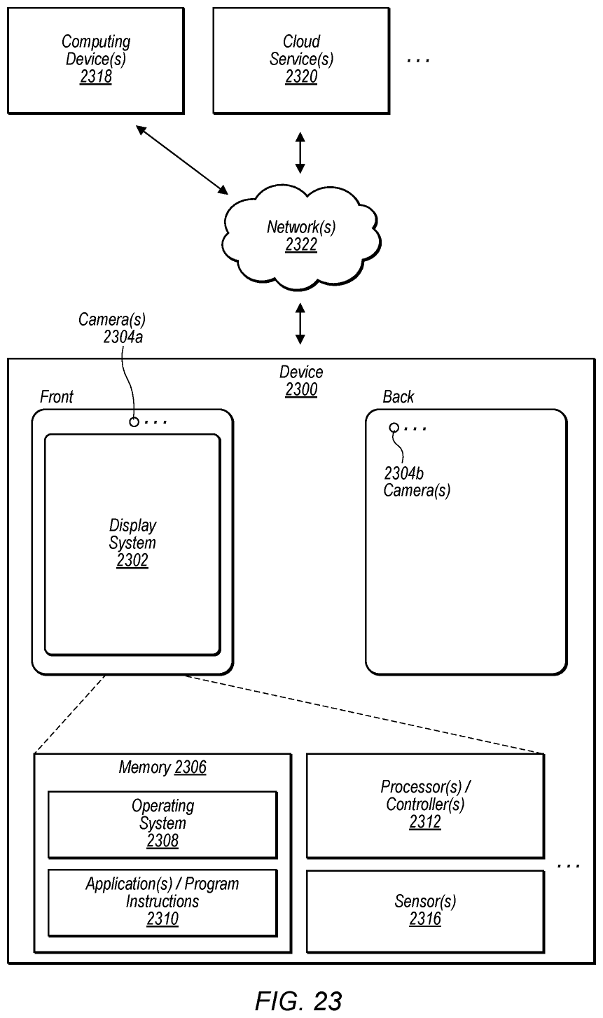

FIG. 23 illustrates a schematic representation of an example device 2300 that may include a camera (e.g., as described herein with respect to FIGS. 1, 2, 3, 4, 5, 6, 7, 8, 9, 10, 11, 12, 13, 14, 15, 16, 17, 18, 19, 20, 21, 22, and 24), in accordance with some embodiments. In some embodiments, the device 2300 may be a mobile device and/or a multifunction device. In various embodiments, the device 2300 may be any of various types of devices, including, but not limited to, a personal computer system, desktop computer, laptop, notebook, tablet, slate, pad, or netbook computer, mainframe computer system, handheld computer, workstation, network computer, a camera, a set top box, a mobile device, an augmented reality (AR) and/or virtual reality (VR) headset, a consumer device, video game console, handheld video game device, application server, storage device, a television, a video recording device, a peripheral device such as a switch, modem, router, or in general any type of computing or electronic device.

In some embodiments, the device 2300 may include a display system 2302 (e.g., comprising a display and/or a touch-sensitive surface) and/or one or more cameras 2304. In some non-limiting embodiments, the display system 2302 and/or one or more front-facing cameras 2304a may be provided at a front side of the device 2300, e.g., as indicated in FIG. 23. Additionally, or alternatively, one or more rear-facing cameras 2304b may be provided at a rear side of the device 2300. In some embodiments comprising multiple cameras 2304, some or all of the cameras may be the same as, or similar to, each other. Additionally, or alternatively, some or all of the cameras may be different from each other. In various embodiments, the location(s) and/or arrangement(s) of the camera(s) 2304 may be different than those indicated in FIG. 23.

Among other things, the device 2300 may include memory 2306 (e.g., comprising an operating system 2308 and/or application(s)/program instructions 2310), one or more processors and/or controllers 2312 (e.g., comprising CPU(s), memory controller(s), display controller(s), and/or camera controller(s), etc.), and/or one or more sensors 2316 (e.g., orientation sensor(s), proximity sensor(s), and/or position sensor(s), etc.). In some embodiments, the device 2300 may communicate with one or more other devices and/or services, such as computing device(s) 2318, cloud service(s) 2320, etc., via one or more networks 2322. For example, the device 2300 may include a network interface (e.g., network interface 2310) that enables the device 2300 to transmit data to, and receive data from, the network(s) 2322. Additionally, or alternatively, the device 2300 may be capable of communicating with other devices via wireless communication using any of a variety of communications standards, protocols, and/or technologies.

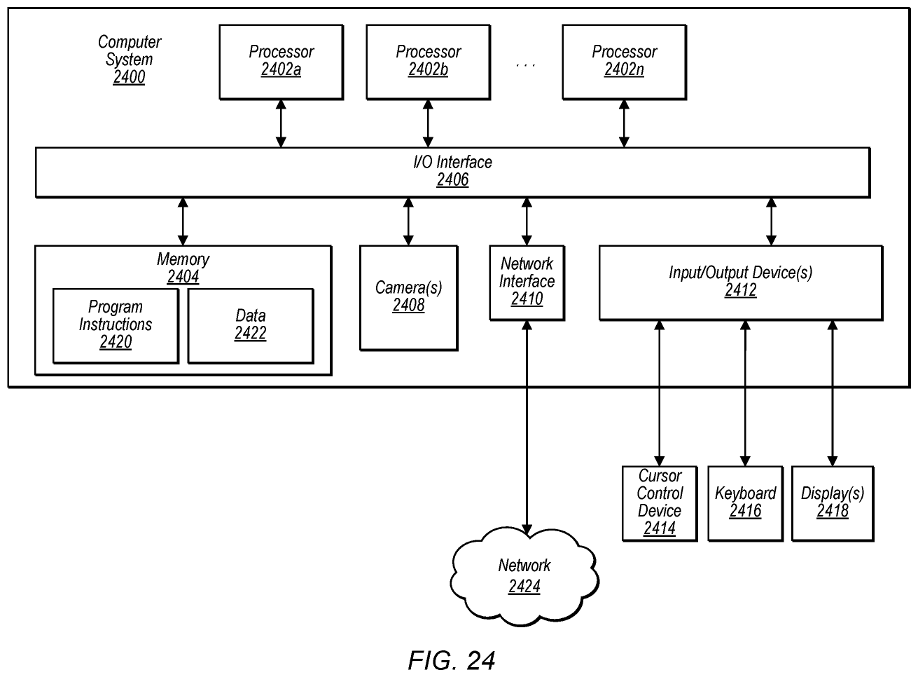

FIG. 24 illustrates a schematic block diagram of an example computing device, referred to as computer system 2400, that may include or host embodiments of a camera (e.g., as described herein with respect to FIGS. 1, 2, 3, 4, 5, 6, 7, 8, 9, 10, 11, 12, 13, 14, 15, 16, 17, 18, 19, 20, 21, 22, and 23). In addition, computer system 2400 may implement methods for controlling operations of the camera and/or for performing image processing images captured with the camera. In some embodiments, the device 2400 (described herein with reference to FIG. 24) may additionally, or alternatively, include some or all of the functional components of the computer system 2400 described herein.

The computer system 2400 may be configured to execute any or all of the embodiments described above. In different embodiments, computer system 2400 may be any of various types of devices, including, but not limited to, a personal computer system, desktop computer, laptop, notebook, tablet, slate, pad, or netbook computer, mainframe computer system, handheld computer, workstation, network computer, a camera, a set top box, a mobile device, an augmented reality (AR) and/or virtual reality (VR) headset, a consumer device, video game console, handheld video game device, application server, storage device, a television, a video recording device, a peripheral device such as a switch, modem, router, or in general any type of computing or electronic device.

In the illustrated embodiment, computer system 2400 includes one or more processors 2402 coupled to a system memory 2404 via an input/output (I/O) interface 2406. Computer system 2400 further includes one or more cameras 2408 coupled to the I/O interface 2406. Computer system 2400 further includes a network interface 2410 coupled to I/O interface 2406, and one or more input/output devices 2412, such as cursor control device 2414, keyboard 2416, and display(s) 2418. In some cases, it is contemplated that embodiments may be implemented using a single instance of computer system 2400, while in other embodiments multiple such systems, or multiple nodes making up computer system 2400, may be configured to host different portions or instances of embodiments. For example, in one embodiment some elements may be implemented via one or more nodes of computer system 2400 that are distinct from those nodes implementing other elements.

In various embodiments, computer system 2400 may be a uniprocessor system including one processor 2402, or a multiprocessor system including several processors 2402 (e.g., two, four, eight, or another suitable number). Processors 2402 may be any suitable processor capable of executing instructions. For example, in various embodiments processors 2402 may be general-purpose or embedded processors implementing any of a variety of instruction set architectures (ISAs), such as the x86, PowerPC, SPARC, or MIPS ISAs, or any other suitable ISA. In multiprocessor systems, each of processors 2402 may commonly, but not necessarily, implement the same ISA.

System memory 2404 may be configured to store program instructions 2420 accessible by processor 2402. In various embodiments, system memory 2404 may be implemented using any suitable memory technology, such as static random access memory (SRAM), synchronous dynamic RAM (SDRAM), nonvolatile/Flash-type memory, or any other type of memory. Additionally, existing camera control data 2422 of memory 2404 may include any of the information or data structures described above. In some embodiments, program instructions 2420 and/or data 2422 may be received, sent or stored upon different types of computer-accessible media or on similar media separate from system memory 2404 or computer system 2400. In various embodiments, some or all of the functionality described herein may be implemented via such a computer system 2400.

In one embodiment, I/O interface 2406 may be configured to coordinate I/O traffic between processor 2402, system memory 2404, and any peripheral devices in the device, including network interface 2410 or other peripheral interfaces, such as input/output devices 2412. In some embodiments, I/O interface 2406 may perform any necessary protocol, timing or other data transformations to convert data signals from one component (e.g., system memory 2404) into a format suitable for use by another component (e.g., processor 2402). In some embodiments, I/O interface 2406 may include support for devices attached through various types of peripheral buses, such as a variant of the Peripheral Component Interconnect (PCI) bus standard or the Universal Serial Bus (USB) standard, for example. In some embodiments, the function of I/O interface 2406 may be split into two or more separate components, such as a north bridge and a south bridge, for example. Also, in some embodiments some or all of the functionality of I/O interface 2406, such as an interface to system memory 2404, may be incorporated directly into processor 2402.

Network interface 2410 may be configured to allow data to be exchanged between computer system 2400 and other devices attached to a network 2424 (e.g., carrier or agent devices) or between nodes of computer system 2400. Network 2424 may in various embodiments include one or more networks including but not limited to Local Area Networks (LANs) (e.g., an Ethernet or corporate network), Wide Area Networks (WANs) (e.g., the Internet), wireless data networks, some other electronic data network, or some combination thereof. In various embodiments, network interface 2410 may support communication via wired or wireless general data networks, such as any suitable type of Ethernet network, for example; via telecommunications/telephony networks such as analog voice networks or digital fiber communications networks; via storage area networks such as Fibre Channel SANs, or via any other suitable type of network and/or protocol.

Input/output devices 2412 may, in some embodiments, include one or more display terminals, keyboards, keypads, touchpads, scanning devices, voice or optical recognition devices, or any other devices suitable for entering or accessing data by one or more computer systems 2400. Multiple input/output devices 2412 may be present in computer system 2400 or may be distributed on various nodes of computer system 2400. In some embodiments, similar input/output devices may be separate from computer system 2400 and may interact with one or more nodes of computer system 2400 through a wired or wireless connection, such as over network interface 2410.

Those skilled in the art will appreciate that computer system 2400 is merely illustrative and is not intended to limit the scope of embodiments. In particular, the computer system and devices may include any combination of hardware or software that can perform the indicated functions, including computers, network devices, Internet appliances, PDAs, wireless phones, pagers, etc. Computer system 2400 may also be connected to other devices that are not illustrated, or instead may operate as a stand-alone system. In addition, the functionality provided by the illustrated components may in some embodiments be combined in fewer components or distributed in additional components. Similarly, in some embodiments, the functionality of some of the illustrated components may not be provided and/or other additional functionality may be available.

Those skilled in the art will also appreciate that, while various items are illustrated as being stored in memory or on storage while being used, these items or portions of them may be transferred between memory and other storage devices for purposes of memory management and data integrity. Alternatively, in other embodiments some or all of the software components may execute in memory on another device and communicate with the illustrated computer system via inter-computer communication. Some or all of the system components or data structures may also be stored (e.g., as instructions or structured data) on a computer-accessible medium or a portable article to be read by an appropriate drive, various examples of which are described above. In some embodiments, instructions stored on a computer-accessible medium separate from computer system 2400 may be transmitted to computer system 2400 via transmission media or signals such as electrical, electromagnetic, or digital signals, conveyed via a communication medium such as a network and/or a wireless link. Various embodiments may further include receiving, sending or storing instructions and/or data implemented in accordance with the foregoing description upon a computer-accessible medium. Generally speaking, a computer-accessible medium may include a non-transitory, computer-readable storage medium or memory medium such as magnetic or optical media, e.g., disk or DVD/CD-ROM, volatile or non-volatile media such as RAM (e.g. SDRAM, DDR, RDRAM, SRAM, etc.), ROM, etc. In some embodiments, a computer-accessible medium may include transmission media or signals such as electrical, electromagnetic, or digital signals, conveyed via a communication medium such as network and/or a wireless link.

The methods described herein may be implemented in software, hardware, or a combination thereof, in different embodiments. In addition, the order of the blocks of the methods may be changed, and various elements may be added, reordered, combined, omitted, modified, etc. Various modifications and changes may be made as would be obvious to a person skilled in the art having the benefit of this disclosure. The various embodiments described herein are meant to be illustrative and not limiting. Many variations, modifications, additions, and improvements are possible. Accordingly, plural instances may be provided for components described herein as a single instance. Boundaries between various components, operations and data stores are somewhat arbitrary, and particular operations are illustrated in the context of specific illustrative configurations. Other allocations of functionality are envisioned and may fall within the scope of claims that follow. Finally, structures and functionality presented as discrete components in the example configurations may be implemented as a combined structure or component. These and other variations, modifications, additions, and improvements may fall within the scope of embodiments as defined in the claims that follow.

What is claimed is:

1. A portable electronic device, comprising:
a camera module having an optical axis;
a display panel;
a display printed circuit board (PCB) including a cutout centered around the optical axis;
a mounting bracket fixedly coupling the camera module to the display PCB; and
a housing configured to retain the camera module, the display panel, the display PCB, and the mounting bracket therein.

2. The portable electronic device of claim 1, wherein the mounting bracket comprises:
a top bracket fixedly attached to the display PCB; and
a bottom bracket coupled to the top bracket and configured to maintain a position of the camera module at a location along the optical axis.

3. The portable electronic device of claim 2, wherein the top bracket is configured to mitigate movement of the camera module in one or more directions orthogonal to the optical axis.

4. The portable electronic device of claim 2, wherein the mounting bracket further comprises:
a damping structure position between the camera module and the bottom bracket and configured to dampen movement of the camera module in at least a direction parallel to the optical axis.

5. The portable electronic device of claim 2, further comprising:
an isolator positioned around the cutout and on a surface of the display PCB opposite the mounting bracket, wherein the isolator is configured to isolate light from a volume between the display panel and the camera module.

6. The portable electronic device of claim 1, further comprising:
an alert bracket positioned beneath the mounting bracket, wherein the alert bracket comprises one or more alert modules configured to provide physical movement of portable electronic device in response to an event.

7. The portable electronic device of claim 1, further comprising:
a packaged system configured to control one or more electronic functions of the portable electronic device; and
an image signal processor (ISP) in electronic communication with the camera module via one or more electrical traces extending through the mounting bracket and the display PCB, wherein the image signal processor is contained in the packaged system.

8. The portable electronic device of claim 1, wherein the camera module comprises a machine vision camera module.

9. A front display package for a portable electronic device, comprising:
a camera module having an optical axis;
a display panel;
a display printed circuit board (PCB) including a cutout centered around the optical axis;
a mounting bracket fixedly coupling the camera module to the display PCB; and
a transparent cover positioned over the display panel on an opposite side of the display panel from the display PCB.

10. The front display package of claim 9, wherein the mounting bracket comprises:
a top bracket fixedly attached to the display PCB; and
a bottom bracket coupled to the top bracket and configured to maintain a position of the camera module at a location along the optical axis.

11. The front display package of claim 10, wherein the top bracket is configured to mitigate movement of the camera module in one or more directions orthogonal to the optical axis.

12. The front display package of claim 9, wherein the mounting bracket further comprises:
a damping structure position between the camera module and the bottom bracket and configured to dampen movement of the camera module in at least a direction parallel to the optical axis.

13. The front display package of claim 9, further comprising:
an isolator positioned around the cutout and on a surface of the display PCB opposite the mounting bracket, wherein the isolator is configured to isolate light from a volume between the display panel and the camera module.

14. A portable electronic device, comprising:
a camera module having an optical axis;
a display panel;
a display printed circuit board (PCB) including a cutout centered around the optical axis;
a mounting bracket fixedly attached to an interior surface within the portable electronic device and configured to maintain a position of the camera module; and
a housing configured to retain the camera module, the display panel, the display PCB, and the mounting bracket therein.

15. The portable electronic device of claim 14, wherein the mounting bracket is fixedly attached to the interior surface within the portable electronic device via one or more pins extending through the mounting bracket and the interior surface within the portable electronic device, and wherein the interior surface within the portable electronic device comprises at least one of a surface of an alert bracket or an interior surface of the housing.

16. The portable electronic device of claim 14, wherein a structure having the interior surface within the portable electronic device maintains a position of the camera module in a direction along the optical axis and the mounting bracket exerts a compression force on the camera module against the interior surface within the portable electronic device.

17. The portable electronic device of claim 14, wherein further comprising:
a damping structure position between the camera module and the interior surface within the portable electronic device are configured to dampen movement of the camera module in at least a direction parallel to the optical axis.

18. The portable electronic device of claim 14, further comprising:
an isolator positioned around the cutout and on a surface of the display PCB opposite the bracket, wherein the isolator is configured to isolate light from a volume between the display panel and the camera module.

19. The portable electronic device of claim 14, further comprising:
a packaged system configured to control one or more electronic functions of the portable electronic device; and
an image signal processor (ISP) in direct electronic communication with the camera module via one or more electrical traces and the display PCB, wherein the image signal processor is contained in the packaged system.

20. The portable electronic device of claim 14, further comprising:
an attachment receiver configured to receive an attachment device for attaching the portable electronic device to a living body.
